(19) United States
(12) Patent Application Publication
(10) Pub. No.: US 2008/0090175 A1
(43) Pub. Date: Apr. 17, 2008

(54) Positive working light sensitive planographic printing plate material and planographic printing plate manufacturing process employing the same

(75) Inventor: Hidetoshi Ezure, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: KONICA MINOLTA MEDICAL & GRAPHIC, INC., Tokyo (JP)

(21) Appl. No.: 11/906,971

(22) Filed: Oct. 4, 2007

(30) Foreign Application Priority Data
Oct. 17, 2006 (JP) JP2006-282335

(51) Int. Cl. G03C 1/00; G03F 7/00

(52) U.S. Cl. 430/278.1; 430/302

(57) ABSTRACT

Disclosed are a positive working planographic printing plate material comprising an aluminum support and provided thereon, a light sensitive layer, wherein the light sensitive layer contains an alkali soluble resin and pigment having on the surface a development restrainer and a positive working planographic printing plate material comprising an aluminum support and provided thereon, a lower light sensitive layer and an upper light sensitive layer in that order, each layer containing an alkali soluble resin, wherein at least one of the lower and upper light sensitive layers contains a pigment having on the surface a development restrainer.

This application is based on Japanese Patent Application No. 2006-282335, filed on Oct. 17, 2006 in Japanese Patent Office, the entire content of which is hereby incorporated by reference.

### FIELD OF THE INVENTION

The present invention relates to a planographic printing plate material comprising a positive working image formation layer used in a computer to plate (hereinafter referred to as CTP) system, and particularly to a positive working planographic printing plate material capable of forming an image on near infrared laser exposure, which excels in sensitivity, development latitude, chemical resistance, and handling properties (such as safelight property), and a manufacturing process of a planographic printing plate employing the same.

### BACKGROUND OF THE INVENTION

In recent years, printing image data are digitized and a so-called CTP system is widely used which comprises exposing a planographic printing plate material employing laser signals to which the digitized data are converted. Presently, laser technique is markedly developed, and a compact solid or semiconductor laser with high output power, which has an emission wavelength of from near-infrared to infrared regions, is available from the market. Such a laser is extremely useful as a light source for manufacturing a printing plate employing digitized data from a computer.

As an infrared laser sensitive planographic printing plate material, there is proposed a positive working planographic printing plate material comprising a recording layer containing an alkali soluble resin (A) having a phenolic hydroxyl group and such as a cresol novolak resin and an infrared absorbing dye (B) (see WO 97/39384).

In this positive working planographic printing plate material, association structure of the cresol novolak resin is changed at exposed portions by heat generated from the infrared absorbing dye, whereby solubility difference (solubility speed difference) between the exposed and unexposed portions is produced. Employing the solubility difference, development of the exposed planographic printing plate material is carried out to form an image.

However, the proposed planographic printing plate material is small in the solubility speed difference, and therefore has problem in that development latitude is narrow.

In order to solvent the above problem, there is proposed a planographic printing plate material comprising an infrared absorbing dye, an acid generating compound decomposed by heat to generate an acid such as an onium salt, a quinonediazide compound, or a triazine compound and an acid decomposable compound having a ketal group (see Japanese Patent No. 3644002 and Japanese Patent O.P.I. Publication No. 7-285275).

This planographic printing plate material improves development latitude, but the improvement is not sufficient, and further improvement is required. Most of the above-described acid generating compounds have an absorption in the visible wavelength regions (from 350 to 500 nm), and therefore, the planographic printing plate material has inconvenience in that it requires processing under yellow light. In the CTP system, a planographic printing plate material with high sensitivity, which is capable of being recorded through an inexpensive and compact exposure device, is sought. The planographic printing plate material is insufficient in view of sensitivity.

### SUMMARY OF THE INVENTION

The present invention has been made in view of the above. An object of the invention is to provide a positive working planographic printing plate material capable of forming an image on near infrared laser exposure, which excels in sensitivity, development latitude, chemical resistance, and handling properties (such as safelight property), and a manufacturing process of a planographic printing plate employing the same.

### DETAILED DESCRIPTION OF THE INVENTION

The above object of the invention can be attained by the followings:

1. A positive working planographic printing plate material comprising an aluminum support and provided thereon, a light sensitive layer, wherein the light sensitive layer contains an alkali soluble resin and pigment having on the surface a development restrainer.

2. The positive working planographic printing plate material of item 1 above, wherein the development restrainer is a polyalkylene glycol compound.

3. The positive working planographic printing plate material of item 1 above, wherein the pigment is carbon black or a phthalocyanine pigment.

4. The positive working planographic printing plate material of item 1 above, wherein in the pigment having on the surface a development restrainer, the pigment is chemically combined with the development restrainer.

5. The positive working planographic printing plate material of item 1 above, wherein the light sensitive layer further contains an acid generating agent or an acid decomposable compound.

6. The positive working planographic printing plate material of item 5 above, wherein the light sensitive layer further contains an acid generating agent and an acid decomposable compound.

7. A positive working planographic printing plate material comprising an aluminum support and provided thereon, a lower light sensitive layer and an upper light sensitive layer in that order, each layer containing an alkali soluble resin, wherein at least one of the lower and upper light sensitive layers contains a pigment having on the surface a development restrainer.

8. The positive working planographic printing plate material of item 7 above, wherein the development restrainer is a polyalkylene glycol compound.

9. The positive working planographic printing plate material of item 7 above, wherein the pigment is carbon black or a phthalocyanine pigment.

10. The positive working planographic printing plate material of item 7 above, wherein in the pigment having on the surface a development restrainer, the pigment is chemically combined with the development restrainer.

11. The positive working planographic printing plate material of item 7 above, wherein the lower light sensitive layer contains the pigment having on the surface a development restrainer.

12. The positive working planographic printing plate material of item 11 above, wherein the upper light sensitive layer contains an infrared absorbing dye.

13. The positive working planographic printing plate material of item 11 above, wherein the lower layer further contains an acid generating agent or an acid decomposable compound.

14. The positive working planographic printing plate material of item 13 above, wherein the lower layer further contains an acid generating agent and an acid decomposable compound.

15. A manufacturing process of a planographic printing plate comprising the steps of imagewise exposing the positive working light sensitive planographic printing plate material of any one of items 1 through 14 above, employing a laser having an emission wavelength of from 700 to 900 nm, and developing the exposed positive working light sensitive planographic printing plate material with a developer with a pH of less than 13.0.

The present invention will be explained in detail below.

The positive working planographic printing plate material of the invention comprises an aluminum support and provided thereon, a light sensitive layer, wherein the light sensitive layer contains an alkali soluble resin and pigment having on the surface a development restrainer, or the positive working planographic printing plate material of the invention comprises an aluminum support and provided thereon, plural light sensitive layers including an upper light sensitive layer (hereinafter also referred to as upper layer) and a lower light sensitive layer (hereinafter also referred to as lower layer) each containing an alkali soluble resin, the upper light sensitive layer being provided on the lower light sensitive layer, wherein at least one of the plural light sensitive layers contains a pigment having on the surface a development restrainer.

### (Pigment Having on the Surface Development Restrainer)

In the invention, the pigment having on the surface a development restrainer (hereinafter referred to simply as the pigment in the invention) is not specifically limited as long as it is pigment which is chemically combined with the development restrainer or pigment onto which the development restrainer is physically adsorbed.

As pigment used in the pigment in the invention, commercially available pigments and pigments described in Color Index (C.I.) Binran, “Saishin Ganryo Binran” (ed. by Nihon Ganryo Gijutsu Kyokai, 1977), “Saishin Ganryo Oyo Gijutsu” (CMC Publishing Co., Ltd., 1986), and “Insatsu Inki Gijutsu” (CMC Publishing Co., Ltd., 1984) can be used.

Kinds of the pigment include black pigment, yellow pigment, orange pigment, brown pigment, red pigment, violet pigment, blue pigment, green pigment, fluorescent pigment, metal powder pigment, and metal-containing colorants. Typical examples of the pigment include insoluble azo pigment, azo lake pigment, condensed azo pigment, chelate azo pigment, phthalocyanine pigment, anthraquinone pigment, perylene or perynone pigment, thioindigo pigment, quinacridone pigment, dioxazine pigment, isoindolinone pigment, quinophthalone pigment, lake pigment, azine pigment, nitroso pigment, nitro pigment, natural pigment, fluorescent pigment, inorganic pigment, and carbon black. Among these pigments, a phthalocyanine pigment or a black inorganic pigment such as an iron oxide, its compound oxide or carbon black is preferred.

The particle size of the pigment is preferably from 0.01 to 5 μm, more preferably from 0.03 to 1 μm, and still more preferably from 0.05 to 0.5 μm. The above range of the pigment particle size is preferred in providing the effects of the invention. As a dispersion method of pigments, a conventional dispersion method used in manufacture of printing ink or toners can be used. Dispersion devices include an ultrasonic disperser, a sand mill, an atliter, a pearl mill, a super mill, a ball mill, an impeller, a disperser, a KD mill, a colloid mill, a dynatron, a three-roll mill, and a pressure kneader. The details are described in “Saishin Ganryo Oyou Gijutsu” (CMC Publishing Co., Ltd., 1986).

As the development restrainer used in the pigment in the invention, there is mentioned a development restrainer ordinarily used in a conventional planographic printing plate material. Examples thereof include an onium salt, a polyalkylene glycol compound, a lactone compound, an amide compound and a sulfonate compound.

A polyalkylene glycol compound, a lactone compound, and a sulfonate compound are preferred in view of development restraining property. (See Japanese Patent O.P.I. Publication No. 2004-157493, paragraph [0040].) The onium salt is not specifically limited, and typical examples thereof include a quaternary ammonium salt and a sulfonium salt.

The development restrainer preferably used in the pigment in the invention is not specifically limited as long as it is one which is capable of lowering the solubility at exposed portions by its interaction with an alkali soluble resin contained in a light sensitive layer and of being dissolved in a developer at exposed portions due to weak interaction with the alkali soluble resin. A quaternary ammonium salt or a polyalkylene glycol compound is preferred, and a polyethylene glycol compound is more preferred.

Examples of the quaternary ammonium salt include tetraalkylammonium salts, trialkylarylammonium salts, dialkyldiarylammonium salts, alkyltriarylammonium salts, tetraarylammonium salts, cyclic ammonium salts and bicyclic ammonium salts, but are not specifically limited thereto.

Examples of the polyalkylene glycol compound are not specifically limited, but include a compound represented by the following formula (1),

### Formula (1)

R₁—{—O—(R₃—O—)ₘ—R₂}ₙ wherein R₁ represents a monoalcoholic or polyalcoholic residue or a monophenolic or polyphenolic residue; R₂ represents a hydrogen atom, a substituted or unsubstituted alkyl group having a carbon atom number of from 1 to 25, an alkenyl group, an alkinyl group, an alkyloyl group, an aryl group or an acryloyl group; R₃ represents a substituted or unsubstituted alkylene group; m represents an integer of not less than 10 on average; and n represents an integer of from 1 to 4.

Examples of the polyalkylene glycol compound represented by formula (1) include polyethylene glycols, polypropylene glycols, polyethylene glycol alkyl ethers, polypropylene glycol alkyl ethers, polyethylene glycol aryl ethers, polypropylene glycol aryl ethers, polyethylene glycol alkylaryl ethers, polypropylene glycol alkylaryl ethers, polyethylene glycol glycerin esters, polypropylene glycol glycerin esters, polyethylene sorbitol esters, polypropylene glycol sorbitol esters, polyethylene glycol fatty acid esters, polypropylene glycol fatty acid esters, polyethylene glycolated ethylenediamines, polypropylene glycolated ethylenediamines, polyethylene glycolated diethylenetriamines, and polypropylene glycolated diethylenetriamines. Polyethylene glycols are preferred.

Examples of the sulfonate compound include sulfonic acid alkyl esters such as cyclohexyl p-acetoaminobenzene sulfonate and cyclohexyl p-bromobenzene sulfonate, and alkyl sulfonic acid esters as disclosed in Japanese Patent O.P.I. Publication No. 10-224650.

A method of chemically combining a development restrainer with pigment is not specifically limited, however, a method as disclosed in Japanese Patent O.P.I. Publication Nos. 2003-511513, 2000-136341, 2000-1607441, 2004-522820 and 2-5-539131 can be employed.

A method of preparing the pigment in the invention will be described below.

### Preparation of Exemplified Pigment A

In a 500 ml four neck flask with a stirrer, a thermometer and a condenser are placed 50 parts by weight of carbon black (Furnace Black MONARCH 800 with a particle size of 17 nm and a pH of 7, produced by Cabot Corporation), 200 parts by weight of ethyl acetate, and 2 parts by weight of 3-isocyanatopropyltrimetoxy-silane. The resulting mixture was refluxed for 5 hours and cooled to 30° C., added with 3 parts of diethanolamine, and reacted for one hour to fix on the carbon black surface the following group.

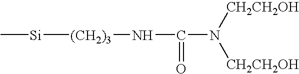

After the reaction, ethyl acetate was removed and the residue was dried to 80° C. for two hours. Thus, Exemplified Pigment A was prepared. The resulting pigment A was dispersed in water in a homogenizer to obtain a carbon black aqueous dispersion having a carbon black concentration of 15% by weight.

The content of the pigment in the invention in the light sensitive layer is preferably from 0.01 to 10% by weight, and more preferably from 0.1 to 5% by weight, in view of sensitivity, or uniformity and durability of the light sensitive layer.

In the invention, various dissolution restrainers can be used in order to adjust solubility. As the dissolution restrainers, there are disulfone compounds or sulfone compounds disclosed in Japanese Patent O.P.I. Publication No. 11-119418. As the dissolution restrainers, 4,4′-bishydroxyphenylsulfone is preferably used.

The content of the dissolution restrainers is preferably from 0.05 to 20% by weight, and more preferably from 0.5 to 10% by weight, based on the weight of layer containing them. The above content range of the dissolution restrainers is preferred in providing the effects of the invention.

### Aluminum Support)

### <Manufacture of Aluminum Support>

As the support used in planographic printing plate material of the invention, an aluminum plate is preferred. The aluminum plate may be a pure aluminum plate or an aluminum alloy plate. As the aluminum alloy, there can be used various ones including an alloy of aluminum and a metal such as silicon, copper, manganese, magnesium, chromium, zinc, lead, bismuth, nickel, titanium, sodium or iron. An aluminum plate can be used which is manufactured according to various calendar procedures. A regenerated aluminum plate can also used which is obtained by calendering ingot of aluminum material such as aluminum scrap or recycled aluminum.

It is preferable that the support in the invention is subjected to degreasing treatment for removing rolling oil prior to surface roughening (graining). The degreasing treatments include degreasing treatment employing solvents such as trichlene and thinner, and an emulsion degreasing treatment employing an emulsion such as kerosene or triethanol. It is also possible to use an aqueous alkali solution such as caustic soda for the degreasing treatment. When an aqueous alkali solution such as caustic soda is used for the degreasing treatment, it is possible to remove soils and an oxidized film which can not be removed by the above-mentioned degreasing treatment alone. When an aqueous alkali solution such as caustic soda is used for the degreasing treatment, the resulting support is preferably subjected to desmut treatment in an aqueous solution of an acid such as phosphoric acid, nitric acid, sulfuric acid, chromic acid, or a mixture thereof, since smut is produced on the surface of the support.

The surface roughening methods include a mechanical surface roughening method and an electrolytic surface roughening method electrolytically etching the support surface. In the invention, the surface roughening method is not specifically limited. The surface roughness Ra of the support is from 0.4 to 0.8 μm. In the invention, surface roughening is preferably carried out in an acidic electrolyte solution containing hydrochloric acid, employing alternating current.

Though there is no restriction for the mechanical surface roughening method, a brushing roughening method and a honing roughening method are preferable. The brushing roughening method is carried out by rubbing the surface of the support with a rotating brush with a brush hair with a diameter of 0.2 to 0.8 mm, while supplying slurry in which volcanic ash particles with a particle size of 10 to 100 μm are dispersed in water to the surface of the support. The honing roughening method is carried out by ejecting obliquely slurry with pressure applied from nozzles to the surface of the support, the slurry containing volcanic ash particles with a particle size of 10 to 100 μm dispersed in water. A surface roughening can be also carried out by laminating a support surface with a sheet on the surface of which abrading particles with a particle size of from 10 to 100 μm was coated at intervals of 100 to 200 μm and at a density of 2.5×10³ to 10×10³/cm², and applying pressure to the sheet to transfer the roughened pattern of the sheet and roughen the surface of the support.

After the support has been roughened mechanically, it is preferably dipped in an acid or an aqueous alkali solution in order to remove abrasives and aluminum dust, etc. which have been embedded in the surface of the support.

Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, an aqueous alkali solution of for example, sodium hydroxide is preferably used. The dissolution amount of aluminum in the support surface is preferably 0.5 to 5 g/m². After the support has been dipped in the aqueous alkali solution, it is preferable for the support to be dipped in an acid such as phosphoric acid, nitric acid, sulfuric acid and chromic acid, or in a mixed acid thereof, for neutralization.

Though there is no restriction for the electrolytic surface roughening method, a method, in which the support is electrolytically surface roughened in an acidic electrolytic solution employing alternating current, is preferred. Though an acidic electrolytic solution generally used for the electrolytic surface roughening can be used, it is preferable to use an electrolytic solution of hydrochloric acid or that of nitric acid.

The electrolytic surface roughening method disclosed in Japanese Patent Publication No. 48-28123, British Patent No. 896,563 and Japanese Patent O.P.I. Publication No. 53-67507 can be used. In the electrolytic surface roughening method, voltage applied is generally from 1 to 50 V, and preferably from 10 to 30 V. The current density used can be selected from the range from 10 to 200 A/dm², and is preferably from 50 to 150 A/dm². The quantity of electricity can be selected from the range of from 100 to 5000 C/dm², and is preferably 100 to 2000 C/dm². The temperature during the electrolytically surface roughening may be in the range of from 10 to 50° C., and is preferably from 15 to 45° C.

When the support is electrolytically surface roughened by using an electrolytic solution of nitric acid, voltage applied is generally from 1 to 50 V, and preferably from 5 to 30V. The current density used can be selected from the range from 10 to 200 A/dm², and is preferably from 20 to 100 A/dm². The quantity of electricity can be selected from the range of from 100 to 5000 C/dm², and is preferably 100 to 2000 C/dm². The temperature during the electrolytically surface roughening may be in the range of from 10 to 50° C., and is preferably from 15 to 45° C. The nitric acid concentration in the electrolytic solution is preferably from 0.1% by weight to 5% by weight. It is possible to optionally add, to the electrolytic solution, nitrates, chlorides, amines, aldehydes, phosphoric acid, chromic acid, boric acid, acetic acid or oxalic acid.

When the support is electrolytically surface roughened by using an electrolytic solution of hydrochloric acid, voltage applied is generally from 1 to 50 V, and preferably from 2 to 30 V. The current density used can be selected from the range from 10 to 200 A/dm², and is preferably from 50 to 150 A/dm². The quantity of electricity can be selected from the range of from 100 to 5000 C/dm², and is preferably 100 to 2000 C/dm². The temperature during the electrolytically surface roughening may be in the range of from 10 to 50° C., and is preferably from 15 to 45° C. The hydrochloric acid concentration in the electrolytic solution is preferably from 0.1% by weight to 5% by weight. It is possible to optionally add, to the electrolytic solution, nitrates, chlorides, amines, aldehydes, phosphoric acid, chromic acid, boric acid, acetic acid or oxalic acid.

After the support has been electrolytically surface roughened, it is preferably dipped in an acid or an aqueous alkali solution in order to remove aluminum dust, etc (desmut treatment). produced in the surface of the support. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, the aqueous alkali solution is preferably used. The dissolution amount of aluminum in the support surface is preferably 0.5 to 5 g/m². After the support has been dipped in the aqueous alkali solution, it is preferable for the support to be dipped in an acid such as phosphoric acid, nitric acid, sulfuric acid and chromic acid, or in a mixed acid thereof, for neutralization.

The mechanical surface roughening and electrolytic surface roughening may be carried out singly, and the mechanical surface roughening followed by the electrolytic surface roughening may be carried out.

After the surface roughening, anodizing treatment may be carried out. There is no restriction in particular for the method of anodizing treatment used in the invention, and known methods can be used.

The anodizing treatment forms an anodization film on the surface of the support. For the anodizing treatment there is preferably used a method of applying a current density of from 1 to 10 A/dm² to an aqueous solution containing sulfuric acid and/or phosphoric acid in a concentration of from 10 to 50%, as an electrolytic solution. However, it is also possible to use a method of applying a high current density to sulfuric acid as described in U.S. Pat. No. 1,412,768, a method to electrolytically etching the support in phosphoric acid as described in U.S. Pat. No. 3,511,661, or a method of employing a solution containing two or more kinds of chromic acid, oxalic acid, malonic acid, etc. The coated amount of the formed anodization film is suitably 1 to 50 mg/dm², and preferably 10 to 40 mg/dm².

The coated amount of the formed anodization film can be obtained from the weight difference between the aluminum plates before and after dissolution of the anodization film. The anodization film of the aluminum plate is dissolved employing for example, an aqueous phosphoric acid chromic acid solution which is prepared by dissolving 35 ml of 85% by weight phosphoric acid and 20 g of chromium (IV) oxide in 1 liter of water.

The cells in the aluminum plate surface after removing the anodization film are observed and then the cell size is measured. The cell size in the invention is preferably from 30 to 80 nm, and more preferably from 40 to 70 nm. The above cell size can minimize development sludge produced during development and improve scratch resistance.

The aluminum plate, which has been subjected to anodizing treatment, is optionally subjected to sealing treatment. For the sealing treatment, it is possible to use known methods using hot water, boiling water, steam, a sodium silicate solution, an aqueous dichromate solution, a nitrite solution and an ammonium acetate solution.

In the mechanical surface roughening or alternating current electrolytically surface roughening employing a nitric acid solution, finely roughened surface having 50 to 1100/μm² of convexo-concavo portions with an average size or an average distance of from 30 to 150 nm is difficult to form. In order to form such a finely roughened surface, sealing treatment is necessary. In this case, treatment with hot water or an ammonium acetate solution is preferred. It is preferred that the treatment with hot water is carried out at 70 to 97° C. for 5 to 180 seconds. In the treatment with an ammonium acetate solution, an ammonium acetate solution having a pH of from 7 to 9.5 provides intended finely roughened surface in a short time.

The alternating current electrolytically surface roughening employing a hydrochloric acid solution can form a finely roughened surface. When the finely roughened surface is dissolved by desmut treatment, the finely roughened surface can be regenerated by treatment employing hot water or an ammonium acetate solution. Further, the finely roughened surface can be formed by a combination of the desmut treatment and the hot water treatment or the ammonium acetate solution treatment.

### <Under Coat Layer (Hydrophilization Processing)>>

After the above treatments, the resulting aluminum plate is preferably subjected to hydrophilization processing. The hydrophilization processing improves adhesion of the support to the lower layer, resulting in improvement of chemical resistance. Further, the layer formed by hydrophilization processing works as an insulating layer. Accordingly, heat generated on infrared ray exposure does not diffuse to the support, and is effectively employed in decomposition of an acid decomposable compound, resulting in high sensitivity.

The hydrophilization processing method is not specifically limited, but there is a method of undercoating, on a support, a water soluble resin such as polyvinyl phosphonic acid, polyvinyl alcohol or its derivatives, carboxymethylcellulose, dextrin or gum arabic; phosphonic acids with an amino group such as 2-aminoethylphosphonic acid; a polymer or copolymer having a sulfonic acid in the side chain; polyacrylic acid; a water soluble metal salt such as zinc borate; a yellow dye; an amine salt; and so on.

The sol-gel treatment support disclosed in Japanese Patent O.P.I. Publication No. 5-304358, which has a functional group capable of causing addition reaction by radicals as a covalent bond, is suitably used. It is preferred that the support is subjected to hydrophilization processing employing polyvinyl phosphonic acid.

As materials for hydrophilization processing, a water soluble infrared absorbing dye can be used. A layer containing the water soluble infrared absorbing dye is preferred in that it works as an insulating layer which prevents heat generated on infrared ray exposure from diffusing to the support, and as a light-to-heat conversion layer specific to the infrared absorbing dye layer. The infrared absorbing dye may be well-known ones and is not specifically limited. Examples thereof include cyanine dyes such as ADS830WS (available from SiberHegner K.K.), sulfonic acids such as NK-4777 (available from Hayashibara Kagaku Kenkyusho), and sulfonates.

As the processing method, there is for example, a coating method, a spraying method or a dipping method. The solution used in the dipping method is preferably an aqueous 0.05 to 3% polyvinyl phosphonic acid solution. The dipping method is preferred in that the facility is cheap. The temperature is preferably from 20 to 90° C., and the processing time is preferably from 10 to 180 seconds. more preferably 40 to 80° C. After the processing, excessive polyvinyl phosphonic acid is removed from the support surface preferably through washing or squeegeeing. After that, drying is preferably carried out.

The drying temperature is preferably from 40 to 180° C., and more preferably from 50 to 150° C. The drying is preferred in increasing adhesion of the hydrophilization processing layer to the support, improving insulating function of the hydrophilization processing layer, and increasing chemical resistance and sensitivity.

The dry thickness of the hydrophilization processing layer is preferably from 0.002 to 0.1 μm, and more preferably from 0.005 to 0.05 μm. The above dry thickness range of the hydrophilization processing layer is preferred in showing the effects of the invention.

### (Surface Form of Support)

The surface of the support is preferably one having a medium wave structure having an average aperture diameter of from 5.0 to 10.0 μm, and superposed thereon, a small wave structure having an average aperture diameter of from 0.5 to 3.0 μm and having an average ratio of aperture depth to aperture diameter of not less than 0.2.

In the invention, the medium wave structure having an average aperture diameter of from 5.0 to 10.0 μm has function carrying an image recording layer due to its anchor effect and increasing printing durability.

The small wave structure having an average aperture diameter of from 0.5 to 3.0 μm and having an average ratio of aperture depth to aperture diameter of not less than 0.2 minimizes printing durability lowering and increases sensitivity. A specific combination of the medium wave structure and small wave structure makes it easy to permeate a developer to the interface between the support and the image recording layer, resulting in increase of development speed.

The medium and small wave structures may be superposed on a large wave structure having an average wavelength of from 5.0 to 100.0 μm. The large wave structure has an effect of increasing a water retention amount at non-image portions of a planographic printing plate. When the water retention amount is more, the non-image portions are more difficult to be contaminated after allowed to stand for long time, and are not affected by environmental contamination. The large wave structure makes it easy to visually judge the amount of dampening water supplied to a printing plate during printing, providing an excellent printing plate detection property.

The average aperture diameter of the medium wave structure, the average aperture diameter and average ratio of aperture depth to aperture diameter of the small wave structure, and the average wavelength of the large wave structure are measured according to the following procedures:

### (1) Average Aperture Diameter of Medium Wave Structure

The surface of the support is photographed through an electron microscope by a factor of 2000 to obtain an electron micrograph. The aperture diameters of at least 50 pits having the medium wave structure (medium wave pits) in the resulting electron micrograph are measured and the average is computed as the average aperture diameter of the medium pits. The same procedure as above is applied to the structure in which the large wave structure is present.

In order to minimize the measurement variation, the equivalent circular diameter measurement can be carried out according to an image analysis soft available on the market. In this case, after the above electron micrograph is read through a scanner and digitized, the digitized data are binaryzed to obtain an equivalent circular diameter.

It has been proved that the results obtained according to the visual measurement are substantially the same as those obtained according to the digital processing. The same results as above are obtained in the structure in which the large wave structure is present.

### (2) Average Aperture Diameter of Small Wave Structure

The surface of the support is photographed by a factor of 50000, employing a high resolution scanning electron microscope (SEM). The aperture diameters of at least 50 pits having the small wave structure (small wave pits) in the resulting SEM photograph are measured and the average is computed as the average aperture diameter of the small pits.

### (3) Average Ratio of Aperture Diameter to Depth in Small Wave Structure

The average ratio of the aperture diameter to the depth of the small wave structure is obtained according the following procedure:

The section of the support is photographed by a factor of 50000, employing a high resolution SEM. The aperture diameter and the depth of at least 20 small wave pits in the resulting SEM photograph are measured and the ratio of the aperture diameter to the depth is obtained.

### (4) Average Wavelength of Large Wave Structure

A two-dimensional measurement of the surface roughness of the support is carried out through a stylus roughness meter, and the average distance Sm between the nearest two peaks defined in ISO 4287 is measured five times, and the average is defined as the average wavelength.

### (Alkali Soluble Resin)

Next, the alkali soluble resin in the invention will be explained.

The alkali soluble resin in the invention refers to a resin which dissolves in an amount of not less than 0.1 g/liter in a 25° C. aqueous potassium hydroxide solution with a pH of 13. As the alkali soluble resins used in the invention, there can be used a phenolic hydroxyl group-containing resin or a combination of a phenolic hydroxyl group-containing resin with (a) a polyacryl resin, (b) a polyacetal resin or (c) a polyurethane resin. Particularly, addition of the above-described alkali soluble resin and an infrared absorbing dye in the upper layer provides high sensitivity and high chemical resistance.

### (Phenolic Hydroxyl Group-Containing Resin)

The phenolic hydroxyl group-containing resin in the invention is one prepared by condensation of various phenols with aldehydes. Examples of the phenols include phenol, m-cresol, p-cresol, a mixed cresol (mixture of m- and p-cresols), a mixture of phenol and cresol (m-cresol, p-cresol or a mixture of m- and p-cresols), pyrogallol, acrylamide having a phenolic hydroxyl group, methacrylamide having a phenolic hydroxyl group, acrylate having a phenolic hydroxyl group, methacrylate having a phenolic hydroxyl group, and hydroxyl styrene.

Other examples of the phenols include substituted phenols such as iso-propylphenol, t-butylphenol, t-amylphenol, hexylphenol, cyclohexylphenol, 3-methyl-4-chloro-6-t-butylphenol, iso-propylcresol, t-butylcresol, and t-amylcresol. Preferred phenols are t-butylphenol and t-butylcresol. Examples of the aldehydes include aliphatic aldehydes such as formaldehyde, acetaldehyde, acrolein and crotonaldehyde; and aromatic aldehydes. Formaldehyde and acetaldehyde are preferred, and formaldehyde is especially preferred.

The preferred examples of the novolak resins include phenol-formaldehyde resin, m-cresol-formaldehyde resin, p-cresol-formaldehyde resin, m-/p-cresol (mixed cresol)-formaldehyde resin, and phenol-cresol (m-cresol, p-cresol, o-cresol, m-/p-cresol (mixed), m-/o-cresol (mixed) or o-/p-cresol (mixed))-formaldehyde resin. Especially preferred is m-/p-cresol (mixed cresol)-formaldehyde resin.

It is preferred that the novolak resin has a weight average molecular weight of not less than 1,000, and a number average molecular weight of not less than 200. It is more preferred that the novolak resin has a weight average molecular weight of from 1,500 to 300,000, a number average molecular weight of from 300 to 250,000, and a polydispersity (weight average molecular weight/number average molecular weight) of from 1.1 to 10. It is still more preferred that the novolak resin has a weight average molecular weight of from 2,000 to 10,000, a number average molecular weight of from 500 to 10,000, and a polydispersity (weight average molecular weight/number average molecular weight) of from 1.1 to 5. In the above molecular weight range, layer strength, alkali solubility, anti-chemical properties and interaction between the novolak resin and a light-to-heat conversion material of a layer containing the novolak resin can be suitably adjusted, whereby the effects of the invention can be easily obtained. The weight average molecular weight of novolak resin contained in the upper or lower layer can be also adjusted. Since the chemical resistance and layer strength is required to be high in the upper layer, the weight average molecular weight of novolak resin contained in the upper layer is preferably relatively high, and preferably from 2,000 to 10,000. The molecular weight of the novolak resin is determined in terms of polystyrene employing monodisperse standard polystyrene according to GPC (gel permeation chromatography).

The novolak resin in the invention can be synthesized according to a method disclosed in for example, “Shi Jikken Kagaku Koza [1,9] Polymer Chemistry [1]”, published by Maruzen Shuppan, p. 300 (1993). That is, phenol or substituted phenols (for example, xylenol or cresol) is dissolved in a solvent, mixed with an aqueous formaldehyde solution, and reacted in the presence of an acid, in which dehydration condensation reaction occurs at the ortho or para position of the phenol or substituted phenols to form a novolak resin. The resulting novolak resin is dissolved in an organic solvent, then mixed with a non-polar solvent and allowed to stand for several hours. The novolak resin mixture forms two phases separated, and the lower phase is concentrated, whereby a novolak resin with a narrow molecular weight distribution is obtained.

The organic solvent used is acetone, methyl alcohol or ethyl alcohol. The non-polar solvent used is hexane or petroleum ether. Further, the synthetic method is not limited to the above. As is disclosed in for example, Japanese Patent O.P.I. Publication No. 2001-506294, the novolak resin is dissolved in a water-soluble organic polar solvent, and then mixed with water to obtain precipitates, whereby a fraction of the novolak resin can be obtained. Further, As a method to obtain a novolak resin with a narrow molecular weight distribution, there is a method in which a novolak resin obtained by dehydration condensation is dissolved in an organic solvent and the resulting solution is subjected to silica gel chromatography for molecular weight fractionation.

Dehydration condensation of phenol with formaldehyde or dehydration condensation of substituted phenols with formaldehyde at o- or p-position of the substituted phenols is carried out as follows:

Phenol or substituted phenols are dissolved in a solvent to obtain a solution having a phenol or substituted phenol concentration of from 60 to 90% by weight, and preferably from 60 to 90% by weight. Then, formaldehyde is added to the resulting solution so that the concentration ratio (by mole) of the formaldehyde to the phenol or substituted phenol is from 0.2 to 2.0, preferably from 0.4 to 1.4, and more preferably from 0.6 to 1.2, and further acid catalyst is added at a reaction temperature of from 10 to 150° C. so that the concentration ratio (by mole) of the acid catalyst to the phenol or substituted phenol is from 0.01 to 0.1, and preferably from 0.02 to 0.05. The resulting mixture is stirred for several hours while maintaining that temperature range.

The reaction temperature is preferably from 70 to 150° C., and more preferably from 90 to 140° C.

The solvent used is, for example, water, acetic acid, methanol, ethanol, 2-propanol, 2-methoxyethanol, ethyl propionate, ethoxyethyl propionate, 4-methyl-2-pentanone, dioxane, xylene or benzene.

The acid catalyst used is hydrochloric acid, sulfuric acid, p-toluene sulfonic acid, phosphoric acid, oxalic acid, tartaric acid, citric acid, zinc acetate, manganese acetate, cobalt acetate, magnesium methylsulfonate, aluminum chloride, or zinc oxide. The residual monomer or dimer in the novolak resin prepared can be removed by vaporization.

Herein, the general molecular weight distribution adjusting method is described, but the distribution adjusting method of novolak resin suitably used in the invention is not limited to the above. For example, conventional methods of adjusting the molecular weight distribution of novolak resin including a specific acid catalyst or solvent can be used in the invention.

The novolak resin can be used singly or as a mixture of two or more kinds thereof. A combination of two or more kinds of novolak resin makes it possible to effectively provide various properties such as layer strength, alkali solubility, anti-chemical properties and interaction between the novolak resin and a light-to-heat conversion material. When two or more kinds of novolak resin are used in the image recording layer, the weight average molecular weight or m/p ratio difference between them is preferably great. For example, the weight average molecular weight difference between the two or more kinds of novoiak resins is preferably not less than 1000, and more preferably not less than 2000, and the m/p ratio difference between the two or more kinds of novolak resins is preferably not less than 0.2, and more preferably not less than 0.3.

Next, a polyacryl resin, a polyurethane resin or a polyacetal resin, which is used in addition to the phenolic hydroxyl group-containing resin described above, will be explained. Incorporation of the polyacryl resin, polyurethane resin or polyacetal resin can greatly improve chemical resistance of layer.

### (Polyacryl Resin)

The polyacryl resin used in the invention is preferably a copolymer containing a constituent unit derived from other monomers in addition to a constituent unit derived from (meth)acrylates. Examples of other monomers include (meth)acrylamides, vinyl esters, styrenes, (meth)acrylic acid, acrylonitrile, maleic anhydride, maleic imide, and lactones.

Examples of the acrylates include methyl acrylate, ethyl acrylate, (n- or i-)propyl acrylate, (n-, i- or sec- or tert-)butyl acrylate, amyl acrylate, 2-ethylhexyl acrylate, dodecyl acrylate, 2-chloroethyl acrylate, 2-hydroxyethyl acrylate, 2-hydroxypropyl acrylate, 5-hydroxypentyl acrylate, cyclohexyl acrylate, allyl acrylate, trimethylpropane monoacrylate, pentaerythritol monoacrylate, glycidyl acrylate, benzyl acrylate, chlorobenzyl acrylate, 2-(p-hydroxyphenyl)ethyl acrylate, furfuryl acrylate, tetrahydrofurfuryl acrylate, phenyl acrylate, chlorophenyl acrylate, and sulfamoylphenyl acrylate.

Examples of the methacrylates include methyl methacrylate, ethyl methacrylate, (n- or i-)propyl methacrylate, (n-, i- or sec- or tert-)butyl methacrylate, amyl methacrylate, 2-ethylhexyl methacrylate, dodecyl methacrylate, 2-chloroethyl methacrylate, 2-hydroxyethyl methacrylate, 2-hydroxypropyl methacrylate, 5-hydroxypentyl methacrylate, cyclohexyl methacrylate, allyl methacrylate, trimethylpropane monomethacrylate, pentaerythritol monomethacrylate, glycidyl methacrylate, benzyl methacrylate, chlorobenzyl methacrylate, 2-(p-hydroxyphenyl)ethyl methacrylate, furfuryl methacrylate, tetrahydrofurfuryl methacrylate, phenyl methacrylate, chlorophenyl methacrylate, and sulfamoylphenyl methacrylate.

Examples of acrylamides include acrylamide, N-methyl acrylamide, N-ethyl acrylamide, N-propyl acrylamide, N-butyl acrylamide, N-benzyl acrylamide, N-hydroxyethyl acrylamide, N-phenyl acrylamide, N-tolyl acrylamide, N-(p-hydroxyphenyl)acrylamide, N-(sulfamoylphenyl)acrylamide, N-(phenylsulfonyl)acrylamide, N-(tolylsulfonyl)acrylamide, N,N-dimethyl acrylamide, N-methyl-N-phenyl acrylamide, N-hydroxyethyl-N-methyl acrylamide, and N-(p-toluenesulfonyl)acrylamide.

Examples of methacrylamides include methacrylamide, N-methyl methacrylamide, N-ethyl methacrylamide, N-propyl methacrylamide, N-butyl methacrylamide, N-benzyl methacrylamide, N-hydroxyethyl methacrylamide, N-phenyl methacrylamide, N-tolyl methacrylamide, N-(p-hydroxyphenyl)methacrylamide, N-(sulfamoylphenyl)methacrylamide, N-(phenylsulfonyl)methacrylamide, N-(tolylsulfonyl)methacrylamide, N,N-dimethyl methacrylamide, N-methyl-N-phenyl methacrylamide, N-hydroxyethyl-N-methyl methacrylamide, and N-(p-toluenesulfonyl)methacrylamide.

Examples of lactones include pantoyl lactone (meth)acrylate, α-(meth)acryloyl-γ-butyrolactone, and β-(meth)acryloyl-γ-butyrolactone.

Examples of maleic imides include maleimide, N-acryloyl acrylamide, N-acetyl methacrylamide, N-propyl methacrylamide, and N-(p-chlorobenzoyl)methacrylamide.

Examples of vinyl ester include vinyl acetate, vinyl butyrate, and vinyl benzoate.

Examples of styrenes include styrene, methylstyrene, dimethylstyrene, trimethylstyrene, ethylstyrene, propylstyrene, cyclohexylstyrene, chloromethylstyrene, trifluoromethylstyrene, ethoxystyrene, acetoxystyrene, methoxystyrene, dimethoxystyrene, chlorostyrene, dichlorostyrene, bromostyrene, iodostyrene, fluorostyrene, and carboxystyrene.

Examples of acrylonitriles include acrylonitrile and methacrylonitrile.

Among these monomers, acrylates or methacrylates having a carbon atom number of not more than 20, acrylamides, methacrylamides, acrylic acid, methacrylic acid, acrylonitriles, or maleic imides are preferably used.

The weight average molecular weight Mw of the polyacryl resin is preferably not less than 2000, more preferably from 5000 to 100000, and still more preferably from 10000 to 50000. The above molecular weight range makes it possible to adjust layer strength, alkali solubility, or chemical resistance of the layer, whereby the advantageous effects of the invention are easily obtained. In the invention, the polyacryl resin may be in the form of random polymer, blocked polymer, or graft polymer, and is preferably a blocked polymer capable of separating a hydrophilic group from a hydrophobic group, in that it can adjust solubility to a developer.

The polyacryl resins used in the invention may be used singly or as a mixture of two or more kinds thereof.

### (Polyacetal Resin)

The polyacetal resin used in the invention can be synthesized by acetalyzing polyvinyl alcohol with aldehydes and reacting the residual hydroxyl group with acid anhydrides. Examples of the aldehydes include formaldehyde, acetaldehyde, propionaldehyde, butylaldehyde, pentylaldehyde, hexylaldehyde, glyoxalic acid, N,N-dimethylformamide, di-n-butylacetal, bromoacetaldehyde, chloroaldehyde, 3-hydroxy-n-butylaldehyde, 3-methoxy-n-butylaldehyde, 3-dimethylamino-2,2-dimethylpropionaldehyde, and cyanoacetaldehyde. In the invention, the aldehyde are not limited thereto.

The polyacetal resin in the invention is preferably a polyvinyl acetal resin represented by the following formula (I):

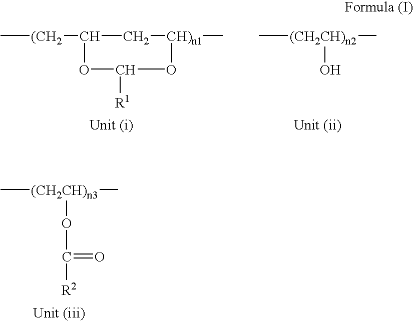

In formula (I), n1 represents 5 to 85 mol % by mole, n2 represents 0 to 60 mol % by mole, and n3 represents 0 to 60 mol %.

The unit (i) is a group derived from vinyl acetal, the unit (ii) is a group derived from vinyl alcohol, and the unit (iii) is a group derived from vinyl ester.

In unit (i), R¹ represents a hydrogen atom, a substituted or unsubstituted alkyl group, an aryl group, a carboxyl group or a dimethylamino group. Examples of the substituent include a carboxyl group, a hydroxyl group, a chlorine atom, a bromine atom, a urethane group, a ureido group, a tertiary amino group, an alkoxy group, a cyano group, a nitro group, an amido group, and an ester group. Examples of R¹ include a hydrogen atom, a methyl group, an ethyl group, a propyl group, a butyl group, a pentyl group, a carboxyl group, a halogen atom (—Br or Cl), a cyanomethyl group, 3-hydroxybutyl group, 3-methoxybutyl group and a phenyl group.

In unit (i), n1 represents 5 to 85% by mole, and preferably 25 to 75% by mole. The above range of n1 is advantageous in layer strength, printing durability or solubility to a solvent for coating.

In unit (ii), n2 represents 0 to 60% by mole, and preferably from 10 to 45% by mole. The unit (ii) is a unit having great affinity to water. The above range of n2 is advantageous in printing durability.

In unit (iii), R² represents an unsubstituted alkyl group, an aliphatic hydrocarbon group having a carboxyl group, an alicyclic group, or an aromatic hydrocarbon group. The hydrocarbon groups have a carbon atom number of from 1 to 20. R² is preferably an alkyl group having a carbon atom number of from 1 to 10, and more preferably a methyl group or an ethyl group. In unit (3), n3 represents 0 to 20% by mole, and preferably from 1 to 10% by mole. The above range of n3 is advantageous in printing durability.

The acid content of the polyvinyl acetal resin in the invention is preferably from 0.5 to 5.0 meq/g (from 84 to 280 in terms of acid value), and more preferably from 0.1 to 3.0 meq/g. The above acid content range is preferred in providing the effects of the invention.

The weight average molecular weight of the polyvinyl acetal resin in the invention is preferably from about 5000 to 400000, and more preferably from about 20000 to 300000, being measured according to gel permeation chromatography. The above molecular weight range makes it possible to adjust layer strength, alkali solubility, or chemical resistance of the layer, whereby the advantageous effects of the invention are easily obtained.

These polyvinyl acetal resins may be used singly or as a mixture of two or more kinds thereof.

The acetalyzation of polyvinyl alcohol can be carried out according to conventional methods disclosed in for example, U.S. Pat. Nos. 4,665,124, 4,940,646, 5,169,898, 5,700,619, and 5,792,823, and Japanese Patent No. 09328519.

### (Polyurethane Resin)

The polyurethane resin used in the invention is not specifically limited, but is preferably alkali soluble polyurethane resin having a carboxyl group in an amount of not less than 0.4 meq/g disclosed in Japanese Patent O.P.I. Publication Nos. 5-281718 and 11-352691. Examples thereof include polyurethane resins having, as a fundamental structure, a unit derived from a diisocyanate compound and a unit derived from a diol compound having a carboxyl group. When the polyurethane resin is synthesized, a diol compound containing no carboxyl group is preferably used in combination in order to adjust the carboxyl group content or physical properties of the resin.

Examples of the diisocyanate include aromatic diisocyanates such as 2,4-tolynene diisocyanate, a dimer of 2,4-tolynene diisocyanate, 2,6-tolynene diisocyanate, p-xylylene diisocyanate, m-xylylene diisocyanate, 4,4′-diphenylmethane diisocyanate, 1,5-naphtylene diisocyanate, and 3,3′-dimethyulbiphenyl-4,4′-diisocyanate; aliphatic diisocyanates such as hexamethylene diisocyanate, trimethylhexamethylene diisocyanate, lysine diisocyanate, and dimer acid diisocyanate; alicyclic diisocyanates such as isophorone diisocyanate, 4,4′-methylenebis(cyclohexyl diisocyanate), methylcyclohexane-2,4-(or 2,6-)diisocyanate, and 1,3-di(isocyanatomethyl)cyclohexane, and an adduct of a diol with a diisocyanate such as a reaction product of 1 mole of butylene glycol with tolylene diisocyanate.

Examples of the diol compound having a carboxyl group include 3,5-dihydroxybenzoic acid, 2,2-bis(hydroxymethyl)propionic acid, 2,2-bis(2-hydroxyethyl)propionic acid, 2,2-bis(3-hydroxypropyl)propionic acid, bis(hydroxymethyl)acetic acid, bis(4-hydroxyphenyl)acetic acid, 2,2-bis(hydroxymethyl)butyric acid, 4,4-bis(4-hydroxyphenyl)pentanoic acid, glutaric acid, N,N-dihydroxyethyl glycine, and N,N-bis(2-hydroxyethyl-3-carboxy-proponamide.

As other diols, there are ethylene glycol, diethylene glycol, triethylene glycol, tetraethylene glycol, propylene glycol, dipropylene glycol, polyethylene glycol, polypropylene glycol, neopentyl glycol, 1,3-butylene glycol, 1,6-hexane diol, 2-butene-1,4-diol, 2,2,4-trimethyl-1,3-pentane diol, 1,4-bis-β-hydroxyethoxycyclohexane, cyclohexane dimethanol, tricyclodecane dimethanol, hydrogenated bisphenol A, hydrogenated bisphenol F, an adduct of bisphenol A with ethylene oxide, an adduct of bisphenol A with propylene oxide, an adduct of bisphenol F with ethylene oxide, an adduct of bisphenol F with propylene oxide, an adduct of hydrogenated bisphenol A with ethylene oxide, an adduct of hydrogenated bisphenol A with propylene oxide, hydroquinone dihydroxyethyl ether, p-xylylene glycol, dihydroxyethylsulfone, bis(2-hydroxyethyl)-2,4-tolylene dicarbamate, 2,4-tolylene-bis(2-hydroxyethylcarbamide), bis(2-hydroxyethyl)-m-xylylene dicarbamate, and bis(2-hydroxyethyl)isophthalate.

As other polyurethane resins suitably used in the invention, there are polyurethanes having a structure unit derived from a ring opening compound obtained by reacting a tetracarboxylic acid dianhydride with a diol. As a method of preparing such polyurethanes, there is a method of reacting diisocyanate with polyol obtained by reacting tetracarboxylic acid dianhydride with diol, or a method of reacting tetracarboxylic acid dianhydride with a urethane compound having a hydroxy group obtained by reacting diisocyanate with excessive diol.

The weight average molecular weight of the polyurethane resins in the invention is preferably not less than 1000, and more preferably from 5000 to 500000.

Further, other resins than the three kinds of resins as described above can be used in the invention, as long as they do not jeopardize the effects of the invention. Examples thereof include polyamide resins, polyester resins, cellulose resins, polyvinyl alcohol or its derivatives, polyvinyl pyrrolidone, epoxy resins, and polyimides.

### (Light-to-Heat Conversion Material)

The light-to-heat conversion material used in the invention refers to a compound having an absorption band in the infrared wavelength regions of from not shorter than 700 nm, and preferably from 750 to 1200 nm, and absorbing and converting the light with those wavelength regions to heat, and typically a dye or pigment generating heat on absorption of light with those wavelength regions.

### (Dyes)

As the dyes, well-known dyes, i.e., commercially available dyes or dyes described in literatures (for example, “Senryo Binran”, edited by Yuki Gosei Kagaku Kyokai, published in 1970) can be used. Examples thereof include azo dyes, metal complex azo dyes, pyrazoline azo dyes, anthraquinone dyes, phthalocyanine dyes, carbonium dyes, quinonimine dyes, methine dyes, and cyanine dyes. Among these dyes or pigments, a dye absorbing an infrared light or a near-infrared light (hereinafter also referred to as an infrared absorbing dye) is preferred in that a laser emitting an infrared light or a near-infrared light can be employed.

Examples of the dye absorbing an infrared light or a near-infrared light include cyanine dyes disclosed in Japanese Patent O.P.I. Publication Nos. 58-125246, 59-84356, and 60-78787, methine dyes disclosed in Japanese Patent O.P.I. Publication Nos. 58-173696, 58-181690, and 58-194595, naphthoquinone dyes disclosed in Japanese Patent O.P.I. Publication Nos. 58-112793, 58-224793, 59-48187, 59-73996, 60-52940, and 60-63744, squarylium dyes disclosed in Japanese Patent O.P.I. Publication Nos. 58-112792, and cyanine dyes disclosed in British Patent No. 434,875.

Further, near infrared absorbing sensitizing dyes described in U.S. Pat. No. 5,156,938 are suitably employed as the dyes. In addition, preferably employed are substituted arylbenzo(thio)pyrylium salts described in U.S. Pat. No. 3,881,924; trimethine-thiapyrilium salts described in Japanese Patent O.P.I. Publication No. 57-142645 (U.S. Pat. No. 4,327,169); pyrylium based compounds described in Japanese Patent O.P.I. Publication Nos. 58-181051, 58-220143, 59-41363, 59-84248, 59-84249, 59-146063, and 59-146061; cyanine dyes described in Japanese Patent O.P.I. Publication No. 59-216146; pentamethinethiopyrylium salts described in U.S. Pat. No. 4,283,475; pyrylium compounds described in Japanese Patent Publication No. 5-13514 and 5-19702, and Epolight III-178, Epolight III-130 or Epolight III-125.

Of these dyes, particularly preferred dyes are cyanine dyes, phthalocyanine dyes, oxonol dyes, squarylium dyes, pyrylium dyes, thiopyrylium dyes, and nickel thiolato complexes. A cyanine dye represented by formula (a) is most preferred in providing high interaction with the alkali soluble resin, excellent stability and excellent economical performance.

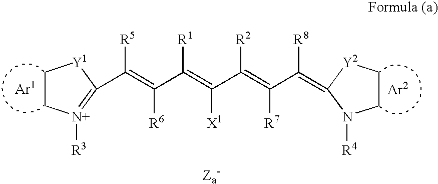

In formula (a), X¹ represents a hydrogen atom, a halogen atom, —Nph₂, X²-L¹ (in which X² represents an oxygen atom or a sulfur atom and L¹ represents a hydrocarbon group having a carbon atom number of from 1 to 12, a hetero atom-containing aromatic ring group or a hetero atom-containing hydrocarbon group having a carbon atom number of from 1 to 12) or a group represented by formula (b) below,

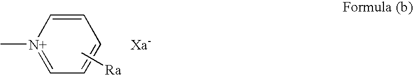

wherein Xa⁻ represents the same as Za⁻ described later, Ra represents a hydrogen atom, an alkyl group, an aryl group, a substituted or unsubstituted amino group, or a halogen atom. The hetero atom herein referred to is N, S, O, a halogen atom, or Se.

R¹ and R² independently represent a hydrocarbon group having a carbon atom number of from 1 to 12. R¹ and R² are preferably a hydrocarbon group having a carbon atom number of not less than 2 in view of stability of the recording layer coating solution. It is especially preferred that R¹ and R² combine with each other to form a 5- or 6-membered ring.

Ar¹ and Ar² independently represent a substituted or unsubstituted aromatic hydrocarbon group, and may be the same or different. Preferred examples of the (unsubstituted) aromatic hydrocarbon groups include a phenyl group or a naphthyl group, and preferred examples of the substituent include a hydrocarbon group having a carbon atom number of not more than 12, a halogen atom or an alkoxy group having a carbon atom number of not more than 12. Y¹ and Y² independently represent a sulfur atom or a diaklylmethylene group having a carbon atom number of not more than 12, and may be the same or different.

R³ and R⁴ independently represent a substituted or unsubstituted hydrocarbon group having a carbon atom number of not more than 20, and may be the same or different. Examples of the substituent include an alkoxy group having a carbon atom number of not more than 12, a carboxyl group or a sulfo group.

R⁵, R⁶, R⁷ and R⁸ independently represent a hydrogen atom or a hydrocarbon group having a carbon atom number of not more than 12, and may be the same or different. R⁵, R⁶, R⁷ and R⁸ are preferably a hydrogen atom in view of availability. Za⁻ represents an anionic group, provided that when the cyanine dye represented by formula (a) forms an intramolecular salt, Za⁻ is not necessary. Preferred examples of Za⁻ include a halogen ion, a perchlorate ion, a tetrafluoroborate ion, a hexafluorophosphate ion, and a sulfonate ion. Especially preferred Za⁻ is a perchlorate ion, a hexafluorophosphate ion or an arylsulfonate ion.

Typical examples of the cyanine dye represented by formula (a) above include ones disclosed in Japanese Patent O.P.I. Publication No. 2001-133969, paragraphs [0017]-[0019], Japanese Patent O.P.I. Publication No. 2002-40638, paragraphs [0012]-[0038], and Japanese Patent O.P.I. Publication No. 2002-23360, paragraphs [0012]-[0023], and ones listed below.

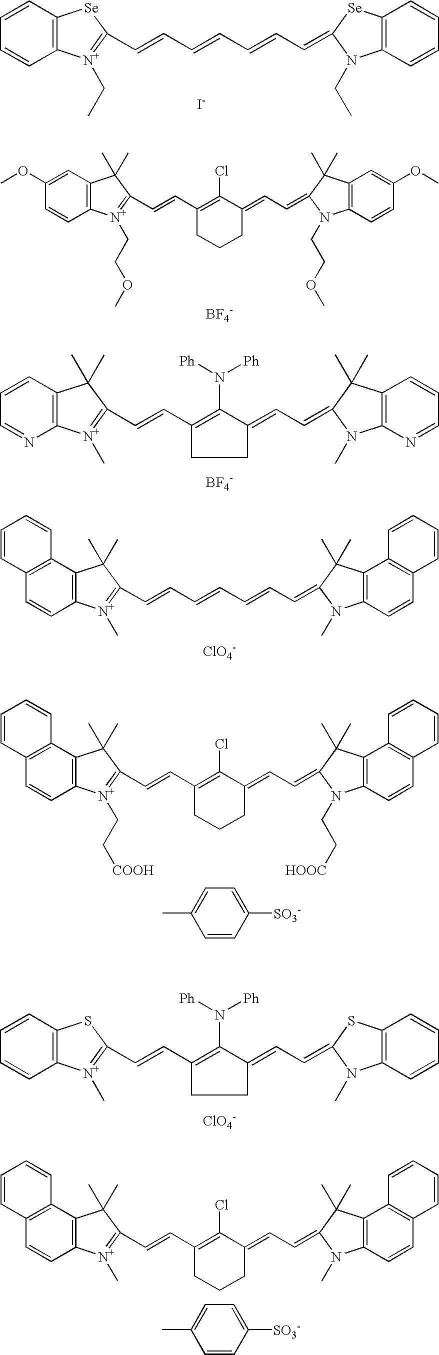

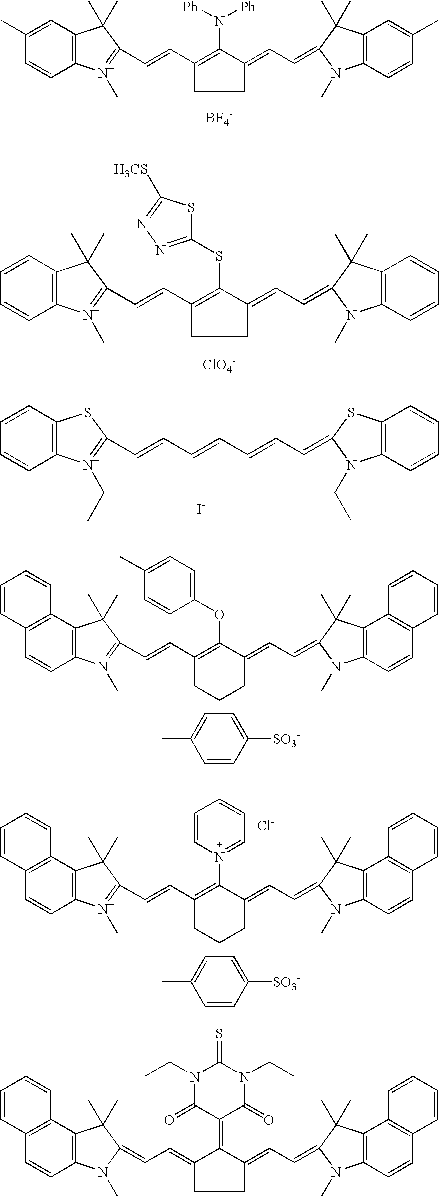

The infrared absorbing dye content of the upper layer in the invention is preferably from 0.01 to 30% by weight, more preferably from 0.1 to 10% by weight, and still more preferably from 0.1 to 7% by weight, in view of sensitivity, chemical resistance and printing durability.

### (Pigment)

Kinds of the pigment include black pigment, yellow pigment, orange pigment, brown pigment, red pigment, violet pigment, blue pigment, green pigment, fluorescent pigment, metal powder pigment, and metal-containing colorants. Typical examples of the pigment include insoluble azo pigment, azo lake pigment, condensed azo pigment, chelate azo pigment, phthalocyanine pigment, anthraquinone pigment, perylene or perynone pigment, thioindigo pigment, quinacridone pigment, dioxazine pigment, isoindolinone pigment, quinophthalone pigment, lake pigment, azine pigment, nitroso pigment, nitro pigment, natural pigment, fluorescent pigment, inorganic pigment, and carbon black. Among these pigments, a phthalocyanine pigment or a black inorganic pigment such as an iron oxide, its compound oxide or carbon black is preferred. The particle size of the pigment is preferably from 0.01 to 5 μm, more preferably from 0.03 to 1 μm, and still more preferably from 0.05 to 0.5 μm.

As a dispersion method of pigments, a conventional dispersion method used in manufacture of printing ink or toners can be used. Dispersion devices include an ultrasonic disperser, a sand mill, an atliter, a pearl mill, a super mill, a ball mill, an impeller, a disperser, a KD mill, a colloid mill, a dynatron, a three-roll mill, and a pressure kneader. The details are described in “Saishin Ganryo Oyou Gijutsu” (CMC Publishing Co., Ltd., 1986).

The pigment can be further added to the lower layer in order to increase sensitivity. The pigments have a low interaction with the alkali soluble resin unlike dyes, and therefore, the addition to the lower layer is preferred, since it increases sensitivity without lowering developing latitude. As pigments, which are added to the lower layer, the pigments as described above can be used. The pigment content of the lower layer in the invention is preferably from 0.1 to 50% by weight, and more preferably from 1 to 20% by weight, in view of layer properties, and sensitivity.

### (Acid Decomposable Compound)

The light sensitive layer of the positive working planographic printing plate material of the invention preferably contains a compound having a chemical bond capable of being decomposed by an acid (an acid decomposable compound). In the invention, it is preferred that the lower layer contains an acid decomposable compound. Examples of the acid decomposable compound include a compound having a C—O—C bond disclosed in Japanese Patent O.P.I. Publication Nos. 48-89003, 51-120714, 53-133429, 55-12995, 55-126236 and 56-17345, a compound having a Si—O—C bond disclosed in Japanese Patent O.P.I. Publication Nos. 60-37549 and 60-121446, another acid decomposable compound disclosed in Japanese Patent O.P.I. Publication Nos. 60-3625 and 60-10247, a compound having a Si—N bond disclosed in Japanese Patent O.P.I. Publication No. 62-222246, a carbonic acid ester disclosed in Japanese Patent O.P.I. Publication No. 62-251743, an orthocarbonic acid ester disclosed in Japanese Patent O.P.I. Publication No. 62-2094561, an orthotitanic acid ester disclosed in Japanese Patent O.P.I. Publication No. 62-280841, an orthosilicic acid ester disclosed in Japanese Patent O.P.I. Publication No. 62-280842, an acetal or ketal disclosed in Japanese Patent O.P.I. Publication No. 2000-221676, a compound having a C—S bond disclosed in Japanese Patent O.P.I. Publication No. 62-244038, and phenolphthalein, cresolphthalein or phenolsulfophthalein each being protected by a thermally decomposable group or an acid decomposable group as disclosed in Japanese Patent O.P.I. Publication No. 2005-91802. Of these compounds, a compound having at least one ketal group or at least one acetal group is preferred, in view of its reaction efficiency with an acid, in other words, sensitivity or developing latitude.

A compound having in the chemical structure —(CH₂CH₂O)n (n represents an integer of from 2 to 5) is preferred in view of balance between sensitivity and development properties. In the above compound, a compound having an ethylene oxy group number of 3 or 4 (n is 3 or 4 in the —(CH₂CH₂O)n) is preferred. Examples of the compound having in the chemical structure —(CH₂CH₂O)n include a condensation product of dimethoxycyclohexane or benzaldehyde or their derivatives with diethylene glycol, triethylene glycol, tetraethylene or pentaethylene glycol.

The acid decomposable compound in the invention is preferably a compound represented by the following formula (ADC-1):

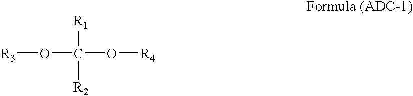

wherein R₁, R₂, R₃ and R₄ independently represent a hydrogen atom, an alkyl group, a cycloalkyl group or an aryl group, provided that they may combine with each other to form a ring. The acid decomposable compound is more preferably a compound represented by the following formula (ADC-2):

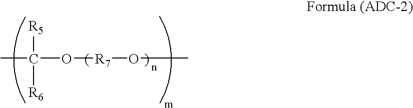

wherein R₅ and R₆ independently represent a hydrogen atom, an alkyl group, a cycloalkyl group, or an aryl group, provided that they may combine with each other to form a ring; R₇ represents an alkylene group, a cycloalkylene group or an arylene group; and n and m independently represent an integer of not less than 1.

The content of the acid decomposable compound in a layer is preferably from 5 to 70% by weight, and more preferably from 10 to 50% by weight, based on the weight of the layer.

The content of the acid decomposable compound in the lower layer is preferably from 0.5 to 50% by weight, and more preferably from 1 to 30% by weight, based on the total solid content of the lower layer, in view of sensitivity, development latitude and safelight properties.

The acid decomposable compound in the invention may be used singly or as an admixture of two or more kinds thereof. The acid decomposable compound in the invention may be contained in the upper layer.

Preferred examples of the acid decomposable compound will be listed below, but are not limited thereto.

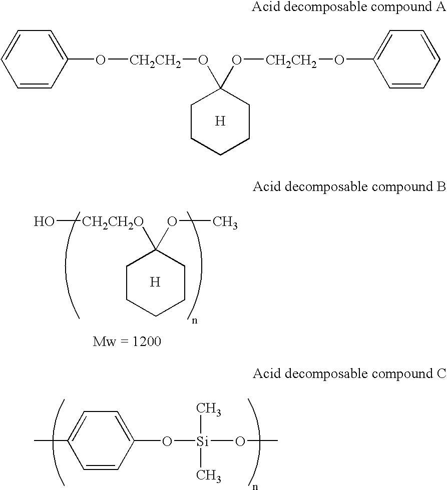

The weight average molecular weight Mw of the acid decomposable compound is preferably from 500 to 30000, and more preferably from 1000 to 10000 in terms of polystyrene, being measured according to gel permeation chromatography (GPC).

### (Acid Generating Agent)

The lower layer in the invention preferably contains an acid generating agent. The acid generating agent is a compound generating an acid on light exposure or heat application. As the acid generating agents, there are various conventional compounds and mixtures.

For example, a salt of diazonium, phosphonium, sulfonium or iodonium ion with BF₄⁻, PF₆⁻, SbF₆⁻SiF₆²⁻ or ClO₄⁻, an organic halogen containing compound, o-quinonediazide sulfonylchloride or a mixture of an organic metal and an organic halogen-containing compound can be used as the acid generating agent in the invention. Further, there are a compound represented by iminosulfonates disclosed in Japanese Patent O.P.I. Publication No. 4-365048, which is photolytically decomposed to generate a sulfonic acid, a disulfone compound disclosed in Japanese Patent O.P.I. Publication No. 61-166544, o-naphthoquinonediazide-4-sulfonic acid halides disclosed in Japanese Patent O.P.I. Publication No. 50-36209 (U.S. Pat. No. 3,969,118), and o-naphthoquinonediazides disclosed in Japanese Patent O.P.I. Publication No. 55-62444 (British patent No. 2038801) and Japanese Patent Publication No. 1-11935. As other examples of acid generating agent there are cyclohexyl citrate, sulfonic acid alkyl esters such as cyclohexyl p-bromobenzene sulfonate and cyclohexyl p-acetoaminobenzene sulfonate, and alkyl sulfonates as disclosed in Japanese Patent Application No. 9-26878.

Among the acid generating agents described above, an organic halogen-containing compound or a compound generating a sulfonic acid is preferred in acid generating performance, in other words, sensitivity or development latitude. Those especially effectively used will be explained below.

### (1) Oxazole Derivatives Represented by Formula (PAG1) or s-Triazine Derivatives Represented by Formula (PAG2) Each Having a Trihalomethyl Group

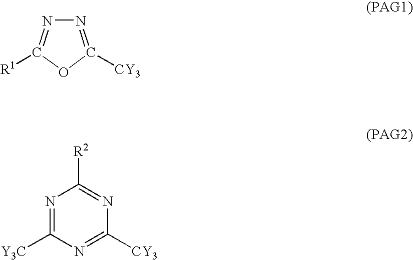

wherein R¹ represents a substituted or unsubstituted aryl group or a substituted or unsubstituted alkenyl group; R² represents a substituted or unsubstituted aryl group, a substituted or unsubstituted alkenyl group, a substituted or unsubstituted alkyl group, or —C(Y₁)₃ in which Y₁ represents a chlorine atom or a bromine atom; and Y represents a chlorine atom or a bromine atom.

Examples thereof will be listed below, but are not limited thereto.

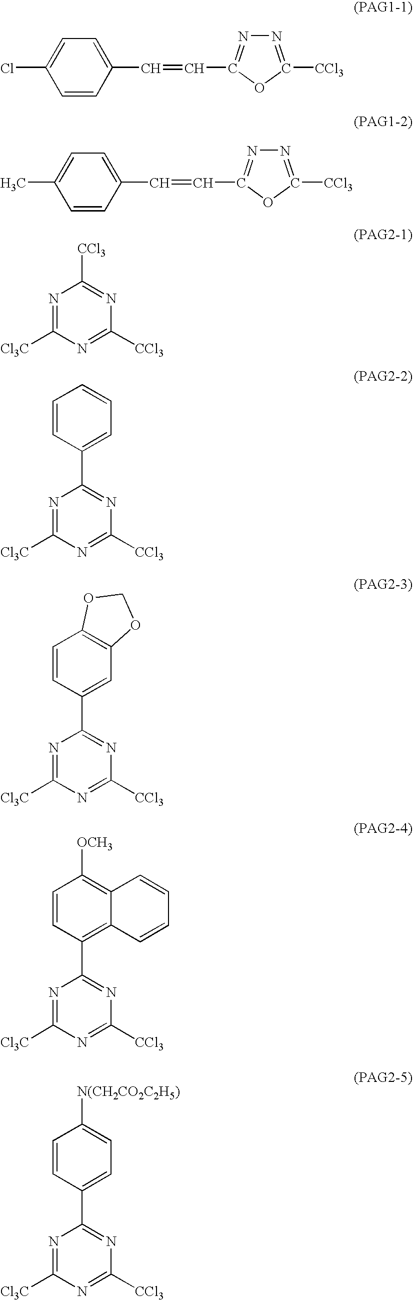

### (2) Disulfone Derivatives Represented by Formula (PAG5) or Iminosulfonate Derivatives Represented by Formula (PAG6)

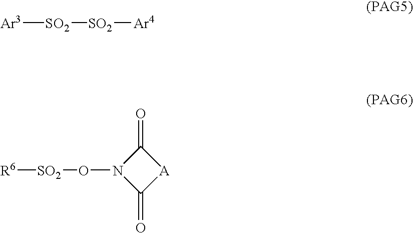

wherein Ar³ and Ar⁴ independently a substituted or unsubstituted aryl group; R⁶ represents a substituted or unsubstituted alkyl group or a substituted or unsubstituted aryl group; and A represents a substituted or unsubstituted alkylene, alkenylene or arylene group.

Examples thereof will be listed below, but are not limited thereto.

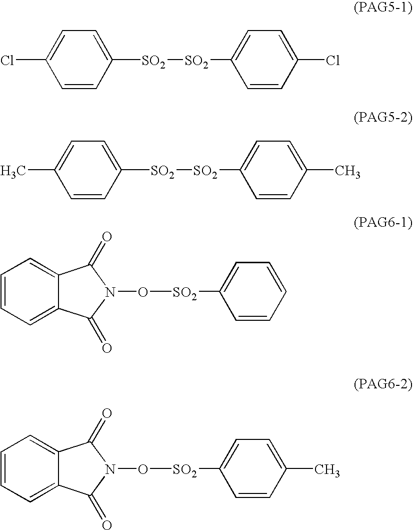

### (3) Halogen Compound Represented by Formula (B) Below Formula (B)

R₁—C(X)₂—C═O)—R₂

wherein R₁ represents a hydrogen atom, a bromine atom, a chlorine atom, an alkyl group, an aryl group, an acyl group, an alkylsulfonyl group, an arylsulfonyl group, an iminosulfonyl group or a cyano group; R₂ represents a hydrogen atom or a monovalent organic substituent, provided that R₁ and R₂ may combine with each other to form a ring; and X represents a bromine atom or a chlorine atom.

Among compounds represented by formula (B), those wherein R₁ is a hydrogen atom, a bromine atom, a chlorine atom are preferred in view of sensitivity. The monovalent organic substituent of R₂ is not limited, as long as the compounds represented by formula (B) generate a radical on light exposure. Those compounds in which in formula (B), R₂ represents —O—R₃ or —NR₄—R₃ (R₃ represents a hydrogen atom or a monovalent organic substituent, and R₄ represents a hydrogen atom or an alkyl group) are preferably employed. Among these, those compounds in which R₁ is a bromine atom or a chlorine atom are more preferably employed in view of sensitivity.

Of these compounds, a compound having at least one haloacetyl group selected from a tribromoacetyl group, a dibromoacetyl group, a trichloroacetyl group, and a dichloroacetyl group is preferred. In view of synthesis, a compound having at least one haloacetoxy group selected from a tribromoacetoxy group, a dibromoacetoxy group, a trichloroacetoxy group, and a dichloroacetoxy group, which is obtained by reacting a monohydric or polyhydric alcohol with a corresponding acid chloride, or a compound having at least one haloacetylamino group selected from a tribromoacetylamino group, a dibromoacetylamino group, a trichloroacetylamino group, and a dichloroacetylamino group, which is obtained by reacting a primary monoamine or primary polyamine with a corresponding acid chloride is especially preferred. Compounds having two or more of each of the haloacetyl group, haloacetoxy group, and haloacetylamino group are preferably used. These compounds can be easily synthesized by conventional esterification or amidation.

Typical synthesis method of the photopolymerization initiator represented by formula (B) is one in which alcohols, phenols or amines are esterified or amidated with acid chlorides such as tribromoacetic acid chloride, diibromoacetic acid chloride, trichlorooacetic acid chloride, or dichloroacetic acid chloride.

The alcohols, phenols or amines used above are arbitrary, and examples thereof include monohydric alcohols such as ethanol, 2-butanol, and 1-adamantanol; polyhydric alcohols such as diethylene glycol, trimethylol propane, and dipentaerythritol; phenols such as phenol, pyrogallol, and naphthol; monoamines such as morpholine, aniline, and 1-aminodecane; and polyamines such as 2,2-dimethylpropylene-diamine, and 1,12-dodecanediamine.

### (4) Polymeric Acid Generating Agent

In the invention, as the acid generating agent, a polymeric acid generating agent having a group capable of generating an acid may be used. The polymeric acid generating agent is preferred since it has both alkali solubility and acid generating function. For example, the alkali soluble resin as described above into which the group capable of generating an acid is incorporated exhibits two or more advantageous effects, for example, excellent chemical resistance of the alkali soluble resin and high sensitivity and development latitude of the acid generating agent.

The polymeric acid generating agent is not specifically limited as long as it has a group capable of generating an acid. However, in the invention, a polymer having a repeating unit derived from an aliphatic monomer represented by the following formula (1) or (2) is preferred in view of sensitivity, development latitude, chemical resistance and handling property.

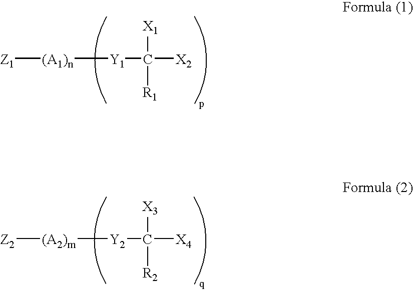

In the invention, a group releasing a halogen radical refers to a group releasing a halogen radical on heat application or light exposure. As such a group, there is, for example, a group represented by formula (3),

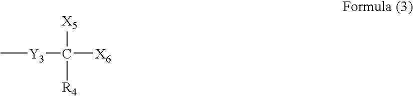

In formula (3), X⁵ and X⁶ independently represent a halogen atom, fluorine, chlorine, bromine or iodine, and may be the same or different. The halogen atom of X⁵ and X⁶ is preferably chlorine, bromine or iodine, more preferably chlorine or bromine and most preferably bromine. R₄ represents a hydrogen atom, a halogen atom or a substituent. Examples of the substituent include an alkyl group, an aryl group, a cycloalkyl group, an alkenyl group, a cycloalkenyl group, an alkinyl group, an amino group, an acyl group, an acyloxy group, an acylamino group, a sulfonylamino group, a sulfamoyl group, a carbamoyl group, an alkylthio group, a sulfonyl group, an alkylsulfonyl group, a sulfinyl group, a cyano group, and a heterocyclic group. R₄ is preferably a halogen atom, and more preferably a bromine atom. Y₃ represents a linkage group. Examples thereof include —SO₂—, —CO—, —NHCO—, —OCO—. SO₂—, and —N(R₅)SO₂—, in which R₆ represents a substituent, for example, a halogen atom, an alkyl group, a cycloalkyl group, an alkenyl group, a cycloalkenyl group, an alkinyl group, an acyloxy group, an alkylthio group, a carboxyl group, an acylamino group, an acyl group or a trifluoromethyl group.

In formula (1) above, X₁ and X₂ independently represent a halogen atom, and may be the same or different. The halogen atom of X₁ and X₂ is preferably chlorine, bromine or iodine, more preferably chlorine or bromine and most preferably bromine. R₁ represents a hydrogen atom or a halogen atom, and is preferably chlorine, bromine or iodine, more preferably chlorine or bromine, and most preferably bromine. Y₁ represents a divalent linkage, and examples of the divalent linkage include —SO₂—, —N(R₆)CO—, in which R₆ is a substituent, or —OCO—. The substituents of R₆ are the same as those denoted in R₅ above. p represents an integer of from 1 to 3. A₁ represents an alkylene group, a cycloalkylene group, an alkenylene group, or an alkinylene group.

These substituents may have further a substituent. Examples of the substituent include a halogen atom (for example, fluorine, chlorine, bromine), an alkyl group (for example, a methyl group, an ethyl group, a propyl group, a butyl group, a pentyl group, an isopentyl group, a 2-ethylhexyl group, an octyl group, or a decyl group), a cycloalkyl group (for example, a cyclohexyl group or a cycloheptyl group), an alkenyl group (for example, an ethenyl-2-propenyl group, a 3-butenyl group, a 1-methyl-3-propenyl group, a 3-pentenyl group, or a 1-methyl-3-butenyl group), a cycloalkenyl group (for example, a 1-cycloalkenyl group or a 2-cycloalkenyl group), an alkinyl group (for example, an ethinyl group or a 1-propinyl group), an alkoxy group (for example, a methoxy group, an ethoxy group or a propoxy group), an alkylcarbonyloxy group (for example, an acetyloxy group), an alkylthio group (for example, a methylthio group or a trifluoromethylthio group), a carboxyl group, an alkylcarbonylamino group (for example, an acetylamino group), a ureido group (for example, a methylaminocarbonylamino group), an alkylsulfonylamino group (for example, a methanesulfonylamino group), an alkylsulfonyl group (for example, a methanesulfonyl group or a trifluoromethane sulfonyl group), a carbamoyl group (for example, a carbamoyl group, an N,N-dimethylcarbamoyl group or an N-molpholinocarbonyl group), a sulfamoyl group (for example, a sulfamoyl group, an N,N-dimethylsulfamoyl group or an N-molpholinosulfamoyl group), a trifluoromethyl group, a hydroxyl group, a nitro group, a cyano group, an alkylsulfonamido group (for example, a methanesulfonamido group or a butanesulfonamido group), an alkylamino group (for example, an N,N-dimethylamino group or an N,N-diethylamino group), a sulfo group, a sulphite group, a sulfino group, an alkylsulfonylaminocarbonyl group (for example, a methanesulfonylaminocarbonyl group or an ethanesulfonylaminocarbonyl group), an alkylcarbonylaminosulfonyl group (for example, an acetoamidosulfonyl group or a methoxyacetoamidosulfonyl group), an alkylaminocarbonyl group (for example, acetoamidocarbonyl group or a methoxyacetoamidocarbonyl group), and an alkylsulfinylaminocarbonyl group (for example, a methanesulfinylaminocarbonyl group or an ethanesulfinylaminocarbonyl group).

When the substituent is plural, the plural substituents may be the same or different. An aryl group and a heteroaryl group are excluded from the substituent. n is 0 or 1, and Z₁ represents an ethylenically unsaturated group, an ethyleneimino group or an epoxy group. Examples of the ethylenically unsaturated group include a vinyl group an isopropenyl group. Z₁ is preferably an ethylenically unsaturated group, and more preferably a vinyl group.

Examples of the compound represented by formula (1) will be listed below, but are not limited thereto.

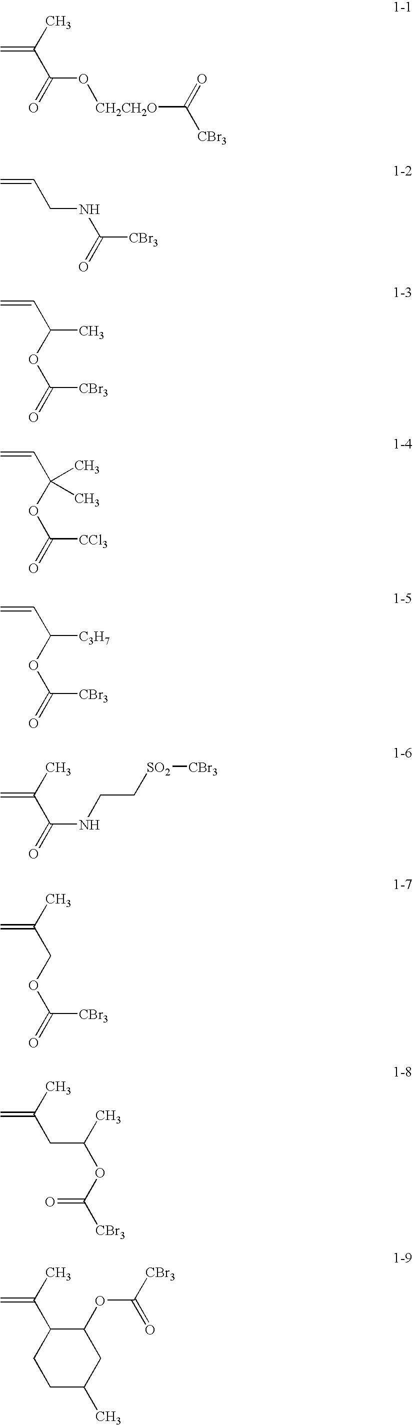

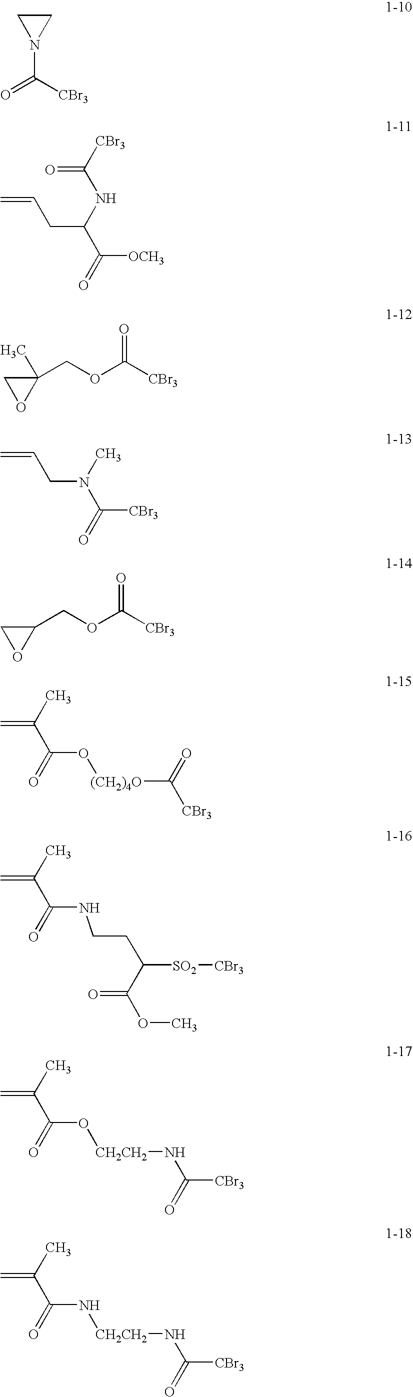

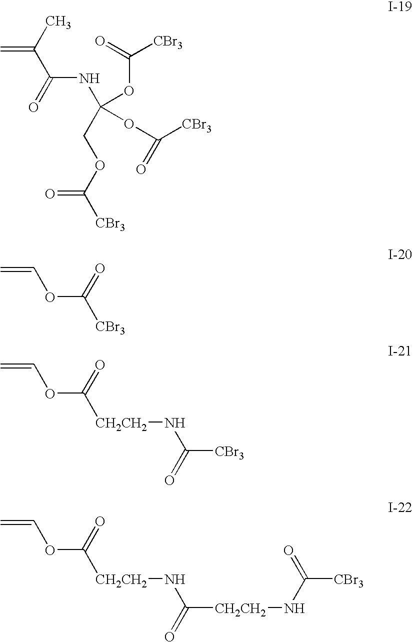

In formula (2) above, X₃ and X₄ independently represent, a halogen atom, and may be the same or different. The halogen atom of X₂ and X₄ is preferably chlorine, bromine or iodine, more preferably chlorine or bromine, and most preferably bromine. R₂ represents a hydrogen atom, a halogen atom or a substituent. The substituents of R₂ are the same as those denoted in R₄ above. Y₂ represents —N(R₃)CO—, in which R₃ is a substituent or —OCO—. The substituents of R₃ are the same as those denoted in R₅ above. q represents an integer of from 1 to 3. A₂ represents an aromatic group or a heterocyclic group. The aromatic group refers to an aryl group having a monocyclic or polycyclic ring having a carbon atom number of from 6 to 30, and preferably from 6 to 20. The aromatic group is preferably a phenyl group or a naphthyl group. Examples of the heterocyclic group include a puridyl group, a pyrazinyl group, a pyrimidyl group, a benzothiazolyl group, a benzimidazolyl group, a thiadiazolyl group, a quinolyl group and an isoquinolyl group. These aromatic and heterocyclic groups may have a substituent. Examples of the substituent include a halogen atom (for example, fluorine, chlorine, bromine), an alkyl group (for example, a methyl group, an ethyl group, a propyl group, a butyl group, a pentyl group, an isopentyl group, a 2-ethylhexyl group, an octyl group, or a decyl group), a cycloalkyl group (for example, a cyclohexyl group or a cycloheptyl group), a cycloalkyl group (for example, a cyclohexyl group or a cycloheptyl group), an aryl group (for example, a phenyl group or a carboxyphenyl group), a heterocyclic group (for example, an imidazolyl group, a thiazolyl group, a benzoxazolyl group, a pyridyl group, a pyrrolyl group, an indolyl group or a pyrimidinyl group), an alkenyl group (for example, an ethenyl-2-propenyl group, a 3-butenyl group, a 1-methyl-3-propenyl group, a 3-pentenyl group, or a 1-methyl-3-butenyl group), a cycloalkenyl group (for example, a 1-cycloalkenyl group or a 2-cycloalkenyl group), an alkinyl group (for example, an ethinyl group or a 1-propinyl group), an alkoxy group (for example, a methoxy group, an ethoxy group or a propoxy group), an acyloxy group (for example, an acetyloxy group or benzoyloxy group), an aryloxy group (for example, a phenoxy group or a p-tolyloxy group), a heteroaryloxy group (for example, a 2-pyridyloxy group or a pyrrolyloxy group), an alkylthio group (for example, a methylthio group or a trifluoromethylthio group), an arylthio group (for example, a phenylthio group or a naphthylthio group), a heteroarylthio group (for example, a 3-thienylthio group or a 3-pyrrolylthio group), an aralkyl group (for example, a benzyl group or a 3-chlorobenzyl group), a carboxyl group, an acylamino group (for example, an acetylamino group or a benzoylamino group), an acyloxycarbonylamino group (for example, an acetyloxycarbonylamino group or benzoyloxycarbonylamino group), a ureido group (for example, a methylaminocarbonylamino group or a pheylaminocarbonylamino group), an sulfonylamino group (for example, a methanesulfonylamino group or a benzenenesulfonylamino group), an acyl group (for example, an acetyl group or a benzoyl group), an sulfonyl group (for example, a methanesulfonyl group or a trifluoromethane sulfonyl group), a carbamoyl group (for example, a carbamoyl group, an N,N-dimethylcarbamoyl group or an N-molpholinocarbonyl group), a sulfamoyl group (for example, a sulfamoyl group, an N,N-dimethylsulfamoyl group or an N-molpholinosulfamoyl group), a trifluoromethyl group, a hydroxyl group, a styryl group, a nitro group, a cyano group, an sulfonamido group (for example, a methanesulfonamido group or a butanesulfonamido group), an amino group (for example, an amino group, an N,N-dimethylamino group or an N,N-diethylamino group), a sulfo group, a phosphono group, a sulphite group, a sulfino group, a sulfonylaminocarbonyl group (for example, a methanesulfonylaminocarbonyl group or an ethanesulfonylaminocarbonyl group), an acylaminosulfonyl group (for example, an acetoamidosulfonyl group or a methoxyacetoamidosulfonyl group), an acylaminocarbonyl group (for example, acetoamidocarbonyl group or a methoxyacetoamidocarbonyl group), and a sulfinylaminocarbonyl group (for example, a methanesulfinylaminocarbonyl group or an ethanesulfinylaminocarbonyl group). When the substituent is plural, the plural substituents may be the same or different. m is 0 or 1, and Z₂ represents an ethylenically unsaturated group, an ethyleneimino group or an epoxy group. Examples of the ethylenically unsaturated group include a vinyl group an isopropenyl group. Z₂ is preferably an ethylenically unsaturated group, and more preferably a vinyl group.

Examples of the compound represented by formula (2) will be listed below, but are not limited thereto.

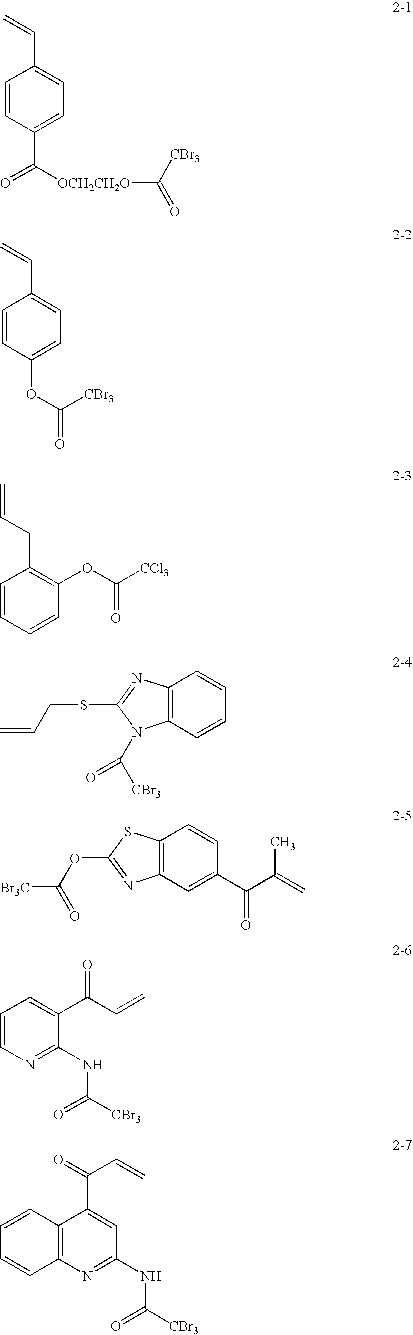

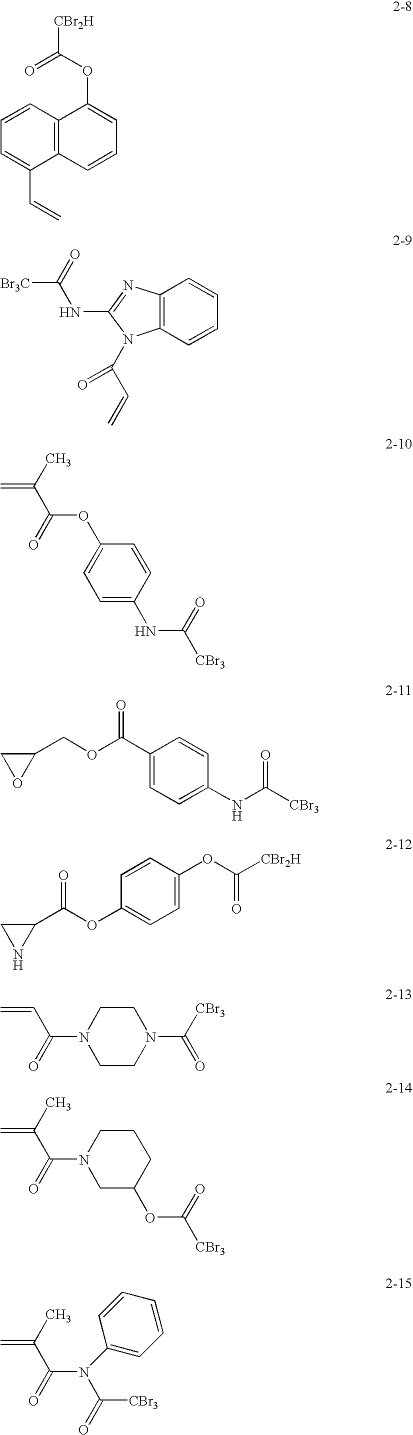

The polymer having a repeating unit derived from the compound represented by formula (1) or (2) can be synthesized as a copolymer by copolymerization of the aliphatic monomer represented by formula (1) or (2) with the monomers used for preparation of the acryl resin described above. The content of the repeating unit derived from the aliphatic monomer represented by formula (3) or (4) in the copolymer is preferably from 1 to 80%, and more preferably from 3 to 50%. The above content range of the repeating unit is preferred in providing the effects of the invention.

The polymer having a repeating unit derived from the aliphatic monomer represented by formula (1) or (2) may be used singly or as a mixture of two or more kinds thereof. Particularly, a combined use of the polymeric acid generating agent and a low molecular weight acid generating agent is preferred in exhibiting the advantageous effects of the invention.

### (5) A compound represented by the following formula (I) is also preferred,

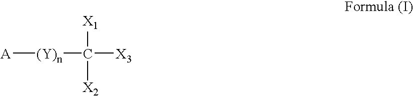

wherein A represents an aliphatic group, an aromatic group, or a heterocyclic group; X₁, X₂ and X₃ independently represent a hydrogen atom or an electron-withdrawing group, which may be the same as or different from each other, provided that X₁, X₂ and X₃ are not simultaneously hydrogen atoms; Y represents a bivalent linkage group; and n is 0 or 1.

The electron-withdrawing group represented by X₁, X₂ and X₃ is a group exhibiting a σp value of preferably not less than 0.01 and more preferably not less than 0.1. Hammett substituent constant (σp) is detailed in Journal of Medicinal Chemistry, 1973, Vol. 16, No. 11, 1207 to 1216.

Examples of the electron-withdrawing group include a halogen atom [e.g., a fluorine atom (Σp of 0.23), an iodine atom (σp of 0.23), a bromine atom (Σp of 0.18), a trihalomethyl group [e.g., tribromomethyl (σp of 0.29), trichloromethyl (σp of 0.33), trifluoromethyl (σp of 0.54)], a cyano group (σp of 0.66), a nitro group (σp of 0.78), an aliphatic, aryl or heterocyclic acyl group [e.g., acetyl (σp of 0.50), benzoyl (σp of 0.43)], an alkynyl group [e.g., C₃H₃ (σp of 0.09)], an aliphatic, aryl or heterocyclic oxycarbonyl group [e.g., methoxycarbonyl (σp of 0.45), phenoxycarbonyl (σp of 0.45)], a carbamoyl group (σp of 0.36), and a sulfamoyl group (σp of 0.57).

X₁, X₂ and X₃ are each preferably an electron-withdrawing group, and more preferably a halogen atom, e.g., fluorine atom (σp of 0.23), iodine atom (σp of 0.23), bromine atom (σp of 0.18), a trihalomethyl group, e.g., tribromomethyl (σp of 0.29), trichloromethyl (σp of 0.33), trifluoeomethyl (σp of 0.54), a cyano group (σp of 0.66), a nitro group (σp of 0.78), an aliphatic, aryl or heterocyclic acyl group, e.g., acetyl (σp of 0.50), benzoyl (σp of 0.43), an alkynyl group, e.g., C₃H₃ (σp of 0.09), an aliphatic, aryl or heterocyclic oxycarbonyl group, e.g., methoxycarbonyl (σp of 0.45), phenoxycarbonyl (σp of 0.45), a carbamoyl group (up of 0.36), and a sulfamoyl group (σp of 0.57); and still more preferably a halogen atom. Of halogen atoms, a chlorine atom, a bromine atom and an iodine atom are preferred and a chlorine atom and a bromine atom are more preferred, and a bromine atom is still more preferred.

Y is a bivalent linkage group and examples thereof include —SO₂—, —SO—, —CO—, —N(R₁₀₁)—SO₂—, —N(R₁₀₁)—CO—, —N(R₁₀₁)—COO—, —COCO—, —COO—, —OCO—, —OCOO—, —SCO—, —SCOO—, —C(Z₁₁) (Z₁₂)-, alkylene, arylene, a bivalent heterocyclic group and a bivalent linkage groups formed by the combination of these groups. R₁₀₁ is a hydrogen atom or an alkyl group, and preferably a hydrogen atom. Z₁₁ and Z₁₂ each are a hydrogen atom or an electron withdrawing group, provided that both of them are not hydrogen atoms at the same time and the electron-withdrawing group preferably is a group exhibiting a Hammett substituent constant (σp) of not less than 0.01, and more preferably not less than 0.1. Preferred electron-withdrawing groups of Z₁₁ and Z₁₂ are the same as those of X₁, X₂ and X₃.

Z₁₁ and Z₁₂ are preferably a halogen atom, cyano, or nitro. The halogen atom is preferably a chlorine atom, a bromine atom and an iodine atom, more preferably a chlorine or bromine atom, and still more preferably a bromine atom. Y is preferably —SO₂—, —SO— or —CO—, and more preferably —SO₂—; and n is preferably 1.

The aliphatic group represented by A is a straight-chain, branched or cyclic alkyl group (preferably having 1 to 30 carbon atoms, more preferably 1 to 20 carbon atoms, and still more preferably 1 to 12 carbon atoms, such as methyl, ethyl, iso-propyl, tert-butyl, n-octyl, n-decyl, cyclopropyl, cyclopentyl and cyclohexyl), an alkenyl group (preferably having 2 to 30 carbon atoms, more preferably 2 to 20 carbon atoms, and still more preferably 2 to 12 carbon atoms, such as vinyl, allyl, 2-butenyl, 3-pentenyl), an alkynyl group (preferably having 2 to 30 carbon atoms, more preferably 2 to 20 carbon atoms, and still more preferably 2 to 12 carbon atoms, such as propargyl, 3-pentynyl), each of which may be substituted. Examples of the substituent group include a carboxyl group, an acyl group, an acylamino group, a sulfonylamino group, a carbamoyl group, an oxycarbonylamino group, and an ureido group. The aliphatic group is preferably an alkyl group, and more preferably a straight chained alkyl group. The aromatic group represented by A is preferably an aryl group; the aryl group is preferably mono-cyclic or di-cyclic aryl group having 6 to 30 carbon atoms (e.g., phenyl, naphthyl), more preferably an aryl group having 6 to 20 carbon atoms, and still more preferably an aryl group having 6 to 12 carbon atoms. The aryl group may be substituted and examples of the substituent group include a carboxy group, an acyl group, an acylamino group, a sulfonylamino group, a carbamoyl group, an oxycarbonylamino group, and a ureido group. The heterocyclic group represented by A is a 3- to 10-member saturated or unsaturated heterocyclic group containing in the ring at least one of N, O and S atoms, which may be monocyclic or polycyclic.

The heterocyclic group represented by A is preferably a 5- or 6-member aromatic heterocyclic group, more preferably a 5- or 6-member aromatic heterocyclic group containing a nitrogen atom, and still more preferably a 5- or 6-member aromatic heterocyclic group containing one or two nitrogen atoms.

Examples of the heterocyclic ring of the heterocyclic group include pyrrolidine, piperidine, piperadine, morpholine, thiophene, furan, pyrrole, imidazole, pyrazolo, pyridine, pirazine, pyridazine, triazole, triazine, indole, indazole, purine, thiadiazole, oxadiazole, quinoline, phthalazine, naphthylidine, quinoquixaline, quinazolone, cinnoline, puteridine, acridine, phenazine, tetrazole, thiazole, oxazole, benzimidazole, benzoxazole, benzthiazole, and indolenine. Of these, thiophene, furan, pyrrole, imidazole, pyrazolo, pyridine, pyrazine, pyridazine, triazole, trazine, indole, indazole, quinoline, thiadiazole, oxadiazole, phthalazine, naphthylidine, quinoxaline, quinazolone, cinnolinepteridine, tetrazole, thiazole, oxazole, benzimidazole, benzoxazole, benzthiazole, and indolenine are preferred; pyridine, triazine, quinoline, thiadiazole, benzthiazole, and oxadiazole are more preferred; and pyridine, quinoline, thiadiazole and oxadiazole are still more preferred.

Of the foregoing polyhalogenated compounds, a compound represented by the following formula (I-a) is more preferred:

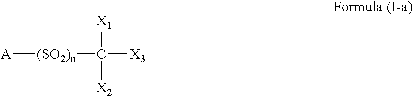

wherein A, X₁, X₂, X₃ and n are the same as defined in formula (I), and the preferred range is also the same as defined in formula (I).

Preferred examples of the polyhalogenated compounds used in the invention will be listed below, but are by no means limited to these.

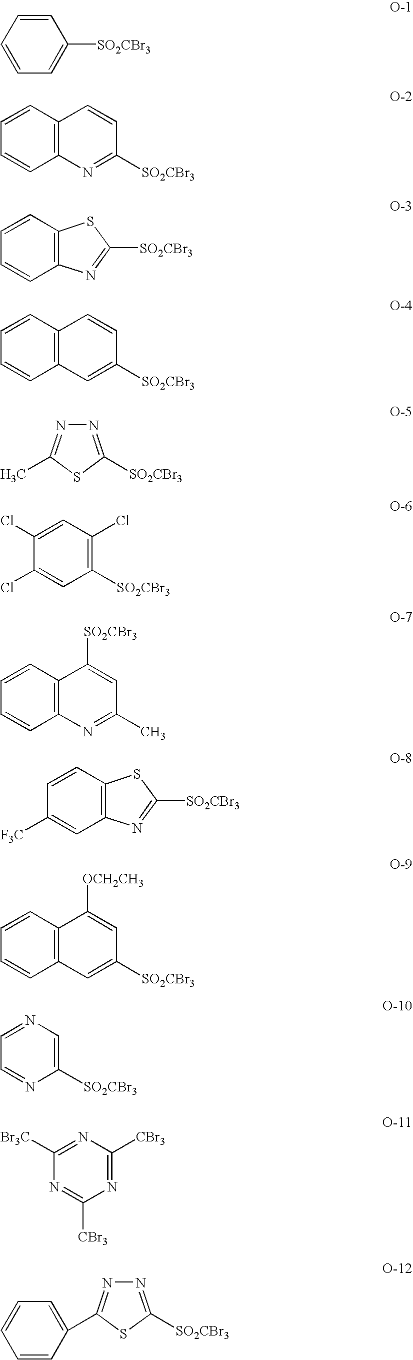

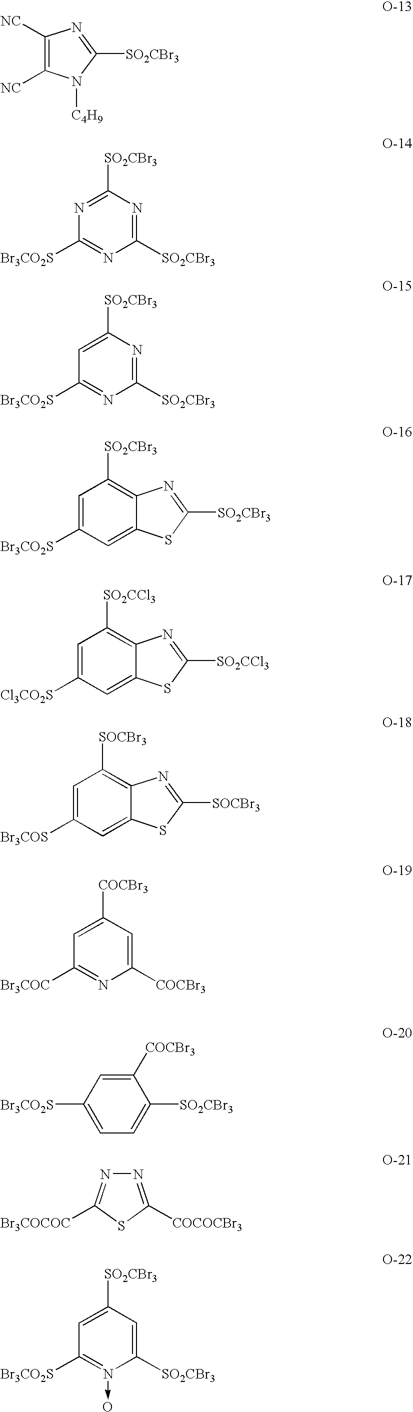

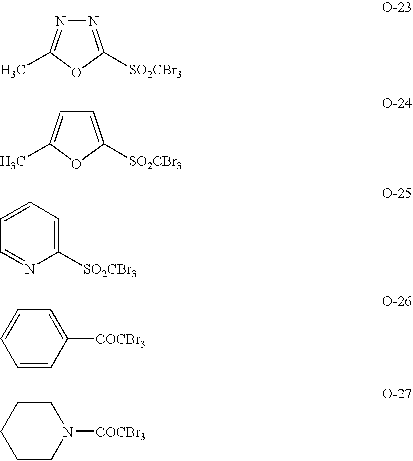

The acid generating agent content of the lower layer is ordinarily from 0.1 to 30% by weight, and preferably from 1 to 15% by weight. The above content range is preferred in providing the effects of the invention.

The acid generating agents may be used singly or as an admixture of two or more kinds thereof. The acid generating agents may be also incorporated into the upper layer as long as they do not lower safelight property. The acid generating agents to be incorporated in the upper layer are preferably those with good safelight property. (Visualizing agent)

As the visualizing agent, other dyes can be employed besides the salt-forming organic dyes as described above. Preferred dyes including the salt-forming organic dyes are oil-soluble dyes and basic dyes. Those changing the color by the action of a free radical or an acid are preferably used.

The term “changing the color” means changing from colorless to color, from color to colorless, or from the color to different color. Preferred dyes are those changing the color by forming salts with an acid.

Examples of the dyes changing from color to colorless or from the color to different color include triphenyl methane, diphenyl methane, oxazine, xanthene, iminonaphthoquinone, azomethine or anthraquinone dyes represented by Victoria pure blue BOH (product of Hodogaya Kagaku), Oil blue #603 (product of Orient Kagaku kogyo), Patent pure blue (product of Sumitomo Mikuni Kagaku Co., Ltd.), Crystal violet, Brilliant green, Ethyl violet, Methyl violet, Methyl green, Erythrosine B, Basic fuchsine, Marachite green, Oil red, m-cresol purple, Rhodamine B, Auramine, 4-p-diethylaminophenyliminonaphthoquinone or cyano-p-diethylaminophenylacetoanilide.

Examples of the dyes changing from colorless to color include leuco dyes and primary or secondary amines represented by triphenylamine, diphenylamine, o-chloroaniline, 1,2,3-triphenylguanidine, diaminodiphenylmethane, p,p′-bis-dimethylaminodiphenylamine, 1,2-dianilinoethylene, p,p′,p″-tris-dimethylaminotriphenylmethane, p,p′-bis-dimethylaminodiphenylmethylimine, p,p′,p″-triamino-o-methyltriphenylmethane, p,p′-bis-dimethylaminodiphenyl-4-anilinonaphthylmethane, and p,p′,p″-triaminotriphenylmethane. These dyes may be used alone or as an admixture of two or more kinds thereof.

Especially preferred dyes are Victoria pure blue BOH (product of Hodogaya Kagaku) and Oil blue #603.

The dye as the visualizing agent can be contained in the lower and/or upper layers, and is preferably contained in the lower layer. As the visualizing agent used in the upper layer, dyes having maximum absorption in the wavelength regions of less than 800 nm, and preferably less than 600 nm are preferably employed. When the acid generating agent is used in the lower layer, the above visualizing agent in the upper layer minimizes transmission of visible light, resulting in preferable results of improving safelight property. Such dyes are preferred since they can be used even when the acid generating agent unfavorable to safelight property is used in the lower layer.

The content of the dye is preferably 0.01 to 10% by weight, and more preferably from 0.1 to 3% by weight, based on the solid weight of layer containing the dyes.

### (Development Accelerator)

The planographic printing plate material of the invention may comprise a compound with a low molecular weight having an acidic group as necessary in order to increase solubility. The acidic groups include acidic groups providing a pKa of from 7 to 11 such as a thiol group, a phenolic hydroxyl group, a sulfonamido group and an active methylene group. The content of that compound is preferably from 0.05 to 5% by weight, and more preferably from 0.1 to 3% by weight, based on the weight of layer containing that compound. The content of the compound exceeding 5% by weight provides an unfavorable tendency to markedly increase solubility of each layer.

### (Development Restrainer)

In the invention, various dissolution restrainers can be used in order to adjust solubility. As the dissolution restrainers, there are disulfone compounds or sulfone compounds disclosed in Japanese Patent O.P.I. Publication No. 11-119418. As the dissolution restrainers, 4,4′-bishydroxyphenylsulfone is preferably used.

The content of the dissolution restrainers is preferably from 0.05 to 20% by weight, and more preferably from 0.5 to 10% by weight, based on the weight of layer containing them. In the invention, development restrainers can be used in order to increase dissolution restraint function.

The development restrainers preferably used in the invention are not specifically limited as long as they are ones which are capable of lowering the solubility at exposed portions by their interaction with the alkali soluble resin described above and of being dissolved in a developer at exposed portions due to weak interaction with the alkali soluble resin. As the restrainers, quaternary ammonium salts or polyethylene glycol derivatives are preferably used.

Examples of the quaternary ammonium salts include tetraalkylammonium salts, trialkylarylammonium salts, dialkyldiarylammonium salts, alkyltriarylammonium salts, tetraarylammonium salts, cyclic ammonium salts and bicyclic ammonium salts, but are not specifically limited thereto.

The content of the quaternary ammonium salts in the upper layer is preferably from 0.1 to 50% by weight, and more preferably from 1 to 30% by weight, based on the weight of the layer. The above content range of the quaternary ammonium salts is preferred in providing the effects of the invention.

However, the method as described above to increase dissolution restraint function lowers sensitivity. In this case, addition of lactone compounds is effective in minimizing the sensitivity lowering. It is considered that when a developer permeates in the layer at exposed portions, i.e., portions free from inhibition, the developer reacts with the lactone compounds to newly generate a carboxylic acid compound, whereby the layer at exposed portions is likely to dissolve and sensitivity increases.

### (Sensitivity Improving Agent)

In the invention, cyclic acid anhydrides, phenols, or organic acids can be used in combination in order to improve sensitivity.

As the cyclic acid anhydrides, there are phthalic anhydride, tetrahydrophthalic anhydride, hexahydrophthalic anhydride, 3,6-endoxy-Δ4-tetrahydrophthalic anhydride, tetrachlorophthalic anhydride, maleic anhydride, chloromaleic anhydride, α-phenylmaleic anhydride, succinic anhydride, pyromellitic anhydride disclosed in U.S. Pat. No. 4,115,128.

As the phenols, there are bisphenol A, p-nitrophenol, p-ethoxyphenol, 2,4,4′-trihydroxybenzophenone, 2,3,4-trihydroxybenzophenone, 4-hydroxybenzophenone, 4,4′,4″-trihydroxytriphenylmethane, and 4,4′,3″,4″-tetrahydroxy-3,5,3′,5′-tetramethylphenylmethane.

As the organic acids, there are sulfonic acids, sulfinic acids, alkyl sulfates, phosphonic acids, phosphates and carboxylic acids disclosed in Japanese Patent O.P.I. Publication Nos. 60-88942 and 2-96744. Examples thereof include p-toluene sulfonic acid, dodecylbenzene sulfonic acid, naphthalene sulfonic acid, p-toluene sulfinic acid, ethyl sulfuric acid, phenyl phosphonic acid, phenyl phosphinic acid, phenyl phosphate, diphenyl phosphate, benzoic acid, isophthalic acid, adipic acid, p-toluic acid, 3,4-dimethoxybenzoic acid, phthalic acid, telephthalic acid, 4-cyclohexene-1,2-dicarboxylic acid, erucic acid, lauric acid, n-undecylic acid, and ascorbic acid.

The content of the cyclic acid anhydrides, phenols or organic acids is preferably from 0.05 to 20% by weight, more preferably from 0.1 to 15% by weight, and still more preferably from 0.1 to 10% by weight, based on the weight of the layer containing them.

Alcohols having in the α-position at least one trifluoromethyl group disclosed in Japanese Patent O.P.I. Publication No. 2005-99298 can be used. This compound increases alkali solubility since acidity of the hydroxy group in the α-position is increased due to electron drawing effect of the trifluoromethyl group.

### (Base Decomposable Compound)

In the invention, compounds newly generating a basic molecule on action of a base may be used. The compounds newly generating a basic molecule on action of a base are compounds generating a basic molecule in the presence of a base or preferably on heating. The generated basic molecule further generates a new basic molecule, followed by chain reaction in which basic molecule generation is continued. Examples thereof include compounds disclosed in Proc. ACS. Polym. Mater. Sci. Eng., vol. 81, 93 (1999) or Angew. Chem. An integer of from. Ed., Vol. 39, 3245 (2000). Preferred examples thereof are compounds represented by formulae (I) through (IV) disclosed in Japanese Patent O.P.I. Publication No. 2004-151138.

### (Back Coat Layer)

The aluminum support of the planographic printing plate material of the invention is preferably an aluminum support having an anodization film on both surfaces. A back coat layer may be provided on a rear surface of the aluminum support (the surface of the aluminum support opposite the upper layer as described above) in order to minimize dissolution of the anodization film on alkali development of the planographic printing plate material. The back coat layer is preferred, since it minimizes sludge produced during development, shorten developer exchange period, and lessens supply amount of developer replenisher. The back coat layer preferably contains (a) metal oxides obtained from hydrolysis or polycondensation of organic or inorganic metal compounds, (b) colloidal silica sol and (c) an organic polymeric compound.

Examples of the metal oxides used in the back coat layer include silica (silicon oxide), titanium oxide, boron oxide, aluminum oxide, zirconium oxide, and their composites. The metal oxides used in the back coat layer is formed by coating a sol-gel reaction solution on the rear surface of the aluminum support and drying it, the sol-gel reaction solution being obtained by hydrolyzing and condensing organic or inorganic metal compounds in water and an organic solvent in the presence of a catalyst such as an acid or an alkali. As the organic or inorganic metal compounds used herein, there are metal alkoxide, metal acetylacetonate, metal acetate, metal oxalate, metal nitrate, metal sulfate, metal carbonate, metal oxychloride, metal chloride, and their oligomers obtained by partially hydrolyzing and condensing these metal compounds.

The metal alkoxide is represented by formula M(OR)n (in which M represents a metal atom, R represents an alkyl group, and n is an oxidation number of the metal atom). Examples of the metal alkoxide include Si(OCH₃)₄, Si(OC₂H₅)₄, Si(OC₃H₇)₄, Si (OC₄H₉)₄, Al(OCH₃)₃, Al(OC₂H₅)₃, Al(OC₃H₇)₃, Al(OC₄H₉)₃, B(OCH₃)₃, B(OC₂H₅)₃, B(OC₃H₇)₃, B(OC₄H₉)₃, Ti (OCH₃)₄, Ti (OC₂H₅)₄, Ti(OC₃H₇)₄, Ti(OC₄H₉)₄, Zr(OCH₃)₄, Zr(OC₂H₅)₄, Zr(OC₃H₇)₄, and Zr(OC₄H₉)₄.

As other metal alkoxides, there are alkoxides of Ge, Li, Na, Fe, Ga, Mg, P, Sb, Sn, Ta, and V. Further, there are monosubstituted silicon alkoxides such as CH₃Si(OCH₃)₃, C₂H₅Si(OCH₃)₃, CH₃Si(OC₂H₅)₃ and C₂H₅Si(OC₂H₅)₃.

Examples of the metal acetylacetonate include Al(COCH₂COCH₃)₃ and Al(COCH₂COCH₃)₄.

Examples of the metal oxalate include K₂TiO(C₂O₄)₂, and examples of the metal nitrate include Al(NO₃)₃ and ZrO(NO₃)₃.2H₂O. Examples of the metal sulfate include Al₂(SO₄)₃, NH₄Al₂(SO₄)₂, KAl₂(SO₄)₂ and NaAl₂(SO₄)₂, examples of the metal oxychloride include Si₂OCl₆ and ZrOCl₂, and examples of the metal chloride include AlCl₃, SiCl₄, ZrCl₂, and TiCl₄.

These organic or inorganic metal compounds may be alone or as an admixture of two or more kinds thereof. Among these organic or inorganic metal compounds, metal alkoxides are preferred since they are reactive and likely to produce polymers comprising metal-oxygen bonds. Among the metal oxides, silicon alkoxides such as Si(OCH₃)₄, Si(OCH₂CH₅)₄, Si(OCH₃CH₇)₄ and Si(OCH₄CH₉)₄ are especially preferred, since they are inexpensive and easily available, and a silicon oxide film derived from the silicon alkoxides is excellent in developer resistance.

Oligomers obtained by partially hydrolyzing and condensing the silicon alkoxides are also preferred. Examples thereof include an ethyl silicate oligomer, which is a pentamer (on average), having about 40% by weight of SiO₂ in the molecule.

It is also preferred that so-called silane coupling agents are employed in combination in which one or two alkoxy groups of a silicon tetraalkoxide are substituted with an alkyl group or a reactive group. Examples thereof include vinyltrimethoxysilane, vinyltriethoxysilane, γ(methacryloxypropyl)trimethoxysilane, β-(3,4-epoxycyclohexyl)ethyltrimethoxysilane, γ-glycidoxypropyltrimethoxysilane, γ-glycidoxypropylmethyl-dimethoxysilane, N-β-(aminoethyl)-γ-aminopropyltrimethoxysilane, N-β-(aminoethyl)-γ-aminopropylmethyldimethoxysilane, γ-aminopropyltriethoxy-silane, N-phenyl-γ-aminopropyltrimethoxysilane, γ-mercaptopropyltrimethoxysilane, γ-chloropropyltrimethoxy-silane, methyltrimethoxysilane and methyltriethoxysilane.

As catalysts, organic or inorganic acids or organic or inorganic alkalis are used. Examples thereof include inorganic acids such as hydrochloric acid, sulfuric acid, sulfurous acid, nitric acid, nitrous acid, hydrofluoric acid, phosphoric acid, and phosphorous acid; organic acids such as formic acid, acetic acid, propionic acid, butyric acid, glycolic acid, chloroacetic acid, trichloroacetic acid, fluoroacetic acid, bromoacetic acid, methoxyacetic acid, oxaloacetic acid, citric acid, oxalic acid, succinic acid, malic acid, glutaric acid, fumalic acid, malonic acid, ascorbic acid, benzoic acid, a substituted benzoic acid such as 3,4-dimethoxybenzoic acid, phenoxyacetic acid, phthalic acid, picric acid, nicotinic acid, picilinic acid, pyrazine, pyrazole, dipicolinic acid, adipic acid, p-toluic acid, telephthalic acid, 1,4-cyclohexene-2,20dicarboxylic acid, erucic acid, lauric acid, and undecanoic acid; alkalis such as hydroxides of an alkali metal or an alkali earth metal, ammonia, ethanolamine, diethanolamine, and triethanoleamine. Other organic acids such as sulfonic acids, sulfonic acids, alkylsulfuric acids, phosphonic acids, and phosphates, for example, p-toluene sulfonic acid, dodecylbenzene sulfonic acid, p-toluenesulfinic acid, ethylsulfuric acid, phenylphosphonic acid, phenylphosphinic acid, phenyl phosphate, diphenyl and phosphate can be used. These catalysts can be used alone or as an admixture of one or more kinds thereof.

The catalysts are used in an amount of preferably from 0.001 to 10% by weight, and more preferably from 0.05 to 5% by weight, based on the weight of the metal compounds used. The above amount range is advantageous in initiation speed of the sol-gel reaction, and formation of uniform sol-gel particles providing excellent developer resistance of metal oxide film formed.

In order to initiate sol-gel reaction in a sol-gel reaction mixture, it is necessary to add an appropriate amount of water thereto. The addition amount of water is preferably 0.05 to 50 times by mole the amount necessary to hydrolyze the metal compound as material completely, and more preferably 0.5 to 30 times by mole the amount necessary to hydrolyze the metal compound as material completely. The above addition amount of water is preferred in promoting the hydrolysis reaction. Solvents are further added to the sol-gel reaction mixture.

The solvents used are ones which dissolve the metal compounds as materials and dissolve or disperse the sol-gel particles formed by sol-gel reaction. Examples thereof include lower alcohols such as methanol, ethanol, propanol and butanol; and ketones such as acetone, methyl ethyl ketone, and diethyl ketone. Monoalkyl ethers, dialkyl ethers or acetates of glycols such as ethylene glycol, diethylene glycol, triethylene glycol, propylene glycol, and dipropylene glycol are also used in order to improve the surface quality of the back coat layer. Among these solvents, lower alcohols are preferred which are miscible with water.

The sol-gel reaction solution is adjusted with solvents to have a solid content suitable for coating. When the total amount of the solvent for the coating solution is used in the sol-gel reaction mixture, the sol-gel reaction mixture is diluted and the hydrolysis reaction is difficult to proceed.

It is preferred that after reaction proceeds to some degree in a sol-gel reaction mixture in which only a part of the solvent for a coating solution is used, the residual solvent for the coating solution is added to the sol-gel reaction mixture to obtain a sol-gel reaction for coating.

The sol-gel reaction proceeds, mixing metal oxides, water, solvents and catalysts. The reaction proceeds depending upon kinds or amount ratio of reaction components used in the reaction mixture, reaction temperature and reaction time, which have an influence on quality of a film to be formed. Particularly, reaction temperature is preferably controlled during reaction, since it has a great influence on the reaction. Compounds having in the molecules a hydroxyl group, an amino group or active hydrogen may be added to the sol-gel reaction mixture in addition to the essential components described above in order to adjust the sol-gel reaction appropriately. Examples thereof include polyethylene glycol, polypropylene glycol, their block copolymer and their monoalkyl ether or monoalkylaryl ether, phenols such as phenol or cresol, polyvinyl alcohol or its copolymer with other vinyl monomers, acids having a hydroxyl group such as malic acid or tartaric acid, aliphatic or aromatic amines, formaldehyde and dimethylformaldehyde. Further, the back coat layer contains an organic polymeric compound in order to increase affinity of the components in the back coat layer to an organic solvent and dissolve them.

Examples of the organic polymeric compound used in the back coat layer include polyvinyl chloride, polyvinyl alcohol, polyvinyl acetate, polyvinyl phenol, polyvinyl halogenated phenol, polyvinyl formal, polyvinyl acetal, polyvinyl butyral, polyamide, polyurethane, polyurea, polyimide, polycarbonate, epoxy resin, phenol novolak, resol, condensation resins of phenols with aldehydes or ketones, polyvinylidene chloride, polystyrene, silicon resin, acryl copolymer having an alkali soluble group such as active methylene, a phenolic hydroxyl group, a sulfonamido group, or a carboxyl group and copolymers derived from two or more kinds thereof. Preferred examples thereof are phenol novolak resin or resol resin, specifically, phenol novolak resin or resol resin obtained by condensation of phenol, cresol (m-cresol, p-cresol, or m-/p-mixed cresol), phenol/cresol (m-cresol, p-cresol, or m-/p-mixed cresol), phenol-modified xylene, tertbutyl phenol, octylphenol, resorcinol, pyrogallol, catechol, chlorophenol (m-Cl or p-Cl), bromophenol (m-Br or p-Br), salicylic acid or phloroglucinol with formaldehyde, or condensation resin obtained by condensation of the above-described phenols with acetone.

Other preferred polymeric compounds include copolymers with a molecular weight of 10000 to 100000 having the following monomer unit (1) to (12) shown below as the constituent.

1) an acrylamide, methacrylamide, acrylate or methacrylate each having an aromatic hydroxy group, or a hydroxystyrene, for example, N-4-hydroxyphenylacrylamide or N-4-hydroxyphenylmethacrylamide, o-, (p- or m-) hydroxystyrene or o-, p- or m-hydroxyphenyl acrylate;

2) An acrylate or methacrylate having an aliphatic hydroxy group, for example, 2-hydroxyethyl acrylate or 2-hydroxyethyl methacrylate;

3) a (substituted) acrylate, for example, methyl acrylate, ethyl acrylate, propyl acrylate, butyl acrylate, amyl acrylate, hexyl acrylate, cyclohexyl acrylate, octyl acrylate, phenyl acrylate, benzyl acrylate, 2-chloroethyl acrylate, 4-hydroxybutyl acrylate, glycidyl acrylate, or N-dimethylaminoethyl acrylate;

4) a (substituted) methacrylate, for example, methyl methacrylate, ethyl methacrylate, propyl methacrylate, butyl methacrylate, amyl methacrylate, hexyl methacrylate, cyclohexyl methacrylate, octyl methacrylate, phenyl methacrylate, benzyl methacrylate, 2-chloroethyl methacrylate, 4-hydroxybutyl methacrylate, glycidyl methacrylate or N-dimethylaminoethyl methacrylate;

5) an acrylamide or methacrylamide, for example, acrylamide, methacrylamide, N-methylolacrylamide, N-methylolmethacrylamide, N-ethylacrylamide, N-ethylmethacrylamide, N-hexylacrylamide, N-hexylmethacrylamide, N-cyclohexylacrylamide, N-cyclohexylmethacrylamide, N-hydroxyethylacrylamide, N-hydroxyethylmethacrylamide, N-phenylacrylamide, N-phenylmethacrylamide, N-benzylacrylamide, N-benzylmethacrylamide, N-nitrophenylacrylamide, N-nitrophenylmethacrylamide, N-ethyl-N-phenylacrylamide or N-ethyl-N-phenylmethacrylamide,

6) a vinyl ether, for example, ethyl vinyl ether, 2-chloroethyl vinyl ether, hydroxyethyl vinyl ether, propyl vinyl ether, butyl vinyl ether, octyl vinyl ether, or phenyl vinyl ether;

7) a vinyl ester, for example, vinyl acetate, vinyl chroloacetate, vinyl butyrate, or vinyl benzoate;

8) a styrene, for example, styrene, methylstyrene, or chloromethystyrene;

9) a vinyl ketone, for example, methyl vinyl ketone, ethyl vinyl ketone, propyl vinyl ketone, or phenyl vinyl ketone;

10) an olefin, for example, ethylene, propylene, isobutylene, butadiene, or isoprene;

11) N-vinylpyrrolidone, N-vinylcarbazole, N-vinylpyridine, acrylonitrile, or methacrylonitrile;

12) an acrylamide, for example, N-(o-aminosulfonylphenyl)acrylamide, N-(m-aminosulfonylphenyl)acrylamide, N-(p-aminosulfonylphenyl)acrylamide, N-[1-(3-aminosulfonyl)naphthyl]acrylamide or N-(2-aminosulfonylethyl)acrylamide; a methacrylamide, for example, N-(o-aminosulfonylphenyl)methacrylamide, N-(m-aminosulfonylphenyl)methacrylamide, N-(p-aminosulfonylphenyl)methacrylamide, N-[1-(3-aminosulfonyl)naphthyl]methacrylamide or N-(2-aminosulfonylethyl)methacrylamide; an acrylate (unsaturated sulfonamide), for example, o-aminosulfonylphenyl acrylate, m-aminosulfonylphenyl acrylate, p-aminosulfonylphenyl acrylate, 1-(3-aminosulfonylphenyl-naphthyl)acrylate; a methacrylate (unsaturated sulfonamide), for example, o-aminosulfonylphenyl methacrylate, m-aminosulfonylphenyl methacrylate, p-aminosulfonylphenyl methacrylate or 1-(3-aminosulfonylphenylnaphthyl)methacrylate.

These polymeric compounds have a weight average molecular weight of preferably 500 to 20000, and a number average molecular weight of preferably 200 to 60000. The polymeric compound content of the back coat layer is preferably 1 to 200% by weight, more preferably 2 to 100% by weight, and still more preferably 5 to 50% by weight of the metal compounds used as materials. The above content range of the polymeric compound is preferred in preventing exfoliation of the back coat layer by chemicals for printing during printing.

When oleophilic substances such as printing ink are adhered to the back coat surface, hydrophilicity of the sol-gel lowers, which makes it difficult to remove the adhered substances.

Examples of the colloidal silica sol used in the back coat layer include a silicon oxide particle colloidal solution employing water, methanol, ethanol, isopropyl alcohol, butanol, xylene, or dimethylformamide as a dispersion medium. Methanol is especially preferred as the dispersion medium. The size of the particles as the dispersoid is preferably from 1 to 100 μm, and more preferably from 10 to 50 μm.

The above size range of the particles is preferred in providing the effects of the invention.

The content of the silicon oxide particles in the solution is preferably from 5 to 80% by weight. The solution, which is not neutral and has a pH outside the range of 6 to 8, is preferred in view of stability. The solution which is acidic is especially preferred.

The silica sol may be used in combination with other particles such as alumina sol or lithium silicate particles, which improve hardness of the sol-gel coated layer. The addition amount of the other particles is preferably from 30 to 300% by weight, more preferably from 30 to 200% by weight, and still more preferably from 50 to 100% by weight, based on the metal compounds used as materials.

The above addition range is preferred in providing the effects of the invention.

### (Coating and Drying)

The lower layer and upper layer of the planographic printing plate material of the invention are ordinarily formed by dissolving the components described above in an appropriate coating solvent to obtain a respective coating solution and coating the coating solution on an appropriate support in order. Coating solvents will be shown below. These solvents may be used singly or as an admixture of two or more kinds thereof.

### (Coating Solvents)

As the coating solvents, there are, for example, n-propanol, isopropyl alcohol, n-butanol, sec-butanol, isobutanol, 2-methyl-1-butanol, 3-methyl-1-butanol, 2-methyl-2-butanol, 2-ethyl-1-butanol, 1-pentanol, 2-pentanol, 3-pentanol, n-hexanol, 2-hexanol, cyclohexanol, methylcyclohexanol, 1-heptanol, 2-heptanol, 3-heptanol, 1-octanol, 4-methyl-2-pentanol, 2-hexylalcohol, benzyl alcohol, ethylene glycol, diethylene glycol, triethylene glycol, tetraethylene glycol, 1,3-propane diol, 1,5-pentane glycol, dimethyl triglycol, furfuryl alcohol, hexylene glycol, hexyl ether, 3-methoxy-1-methylbutanol, butyl phenyl ether, ethylene glycol monoacetate, propylene glycol, monomethylether, propylene glycol monoethylether, propylene glycol monopropylether, propylene glycol monobutylether, propylene glycol phenylether, dipropylene glycol monomethylether, dipropylene glycol monoethylether, dipropylene glycol monopropylether, dipropylene glycol monombutylether, tripropylene glycol monomethylether, methyl carbitol, ethyl carbitol, ethyl carbitol acetate, butyl carbitol, triethylene glycol monomethylether, triethylene glycol monoethylether, tetraethylene glycol dimethylether, diacetone alcohol, acetophenone, cyclohexanone, methyl cyclohexanone, acetonylacetone, isophorone, methyl lactate, ethyl lactate, butyl lactate, propylene carbonate, phenyl acetate, sec-butyl acetate, cyclohexyl acetate, diethyl oxalate, methyl benzoate, ethyl benzoate, γ-butyrolactone, 3-methoxy-1-butanol, 4-methoxy-1-butanol, 3-ethoxy-1-butanol, 3-methoxy-3-methyl-1-butanol, 3-methoxy-3-ethyl-1-pentanol, 4-ethoxy-1-pentanol, 5-methoxy-1-hexanol, 3-hydroxy-2-butanone, 4-hydroxy-2-butanone, 4-hydroxy-2-pentanone, 5-hydroxy-2-pentanone, 4-hydroxy-3-pentanone, 6-hydroxy-2-pentanone, 6-hydroxy-2-hexanone, 3-methyl-3-hydroxy-2-pentanone, methyl cellosolve (MC), and ethyl cellosolve (EC).

Regarding a coating solvent for the upper or lower layer, the coating solvent for the upper layer is preferably different in solvency to an alkali soluble resin from that for the lower layer. When an upper layer coating solution is coated on a lower layer surface, employing, as a coating solvent for the upper layer, a solvent dissolving the alkali soluble resin of the lower layer, the upper layer is mixed with the lower layer at the interface of the two layers, and the extreme cases of the mixing form a uniform single layer. Accordingly, such mixing is undesirable, since it may not show the effects of the invention that the two separate layers in the invention, i.e., the upper and lower layers provide. A solvent used in the upper thermosensitive layer coating solution is preferably a poor solvent of the alkali soluble resin contained in the lower layer.

In order to prevent mixing of the upper and lower layers, there are a method in which air is blown onto the coated surface with high pressure from slit nozzles arranged at right angle to the running direction of web, a method in which heat is supplied as conductive heat onto the rear surface through a heat roll inside which a heated medium such as vapor is supplied, and their combination, whereby a second coated layer coated on a first coated layer is rapidly dried.

As a method for mixing the two layers to the degree that the effects of the invention is produced, there is a method employing the solvency difference as described above of the coating solvents or a method rapidly drying the second coated layer coated on the first coated layer, both of which can adjust the degree.

The coating solution for the upper or lower layer (hereinafter also referred to as image formation layer coating solution) has a total solid content (including additives) of preferably from 1 to 50% by weight.

The dry coating amount of the upper layer, which has been formed on the support, is preferably from 0.05 to 1.0 g/m², although different due to usage, and the dry coating amount of the lower layer is preferably from 0.3 to 3.0 g/m². The above dry coating amount range of the upper or lower layer is preferred in view of image formation properties and sensitivity. The total dry coating amount of the upper and lower layers is preferably from 0.5 to 3.0 g/m².

The above total dry coating amount range of the upper and lower layers is preferred in view of layer properties and sensitivity. When the dry coating amount is less, apparent sensitivity increases but layer properties deteriorate.

The light sensitive layer coating solution is coated on a support according to a conventional method and dried to obtain a planographic printing plate material. As the coating methods, there are an air doctor coating method, a blade coating method, a wire bar coating method, a knife coating method, a dip coating method, a reverse roll coating method, a gravure coating method, a cast coating method, a curtain coating method, and an extrusion coating method.

The drying temperature is preferably from 60 to 160° C., more preferably from 80 to 140° C., and still more from 90 to 120° C. An infrared radiation device can be used as a drying device to improve drying efficiency.

In the invention, a planographic printing plate material obtained as above may be further subjected to aging treatment to stabilize the performance thereof. The aging treatment may be carried out in an aging device provided following a drying device or in an aging device provided separately. As disclosed in Japanese Patent O.P.I. Publication No. 2005-17599, the aging treatment may be used as a step in which OH groups on the layer surface are brought into contact with each other. In the aging treatment, a compound having a polar group represented by water permeates and diffuses from the layer surface to the inside of the layer whereby interaction in the layer is enhanced through water, cohesion is enhanced by heating, and performance of the layer is improved. Temperature at the aging treatment is preferably set so that a specific amount of a compound to diffuse is evaporated. Typical examples of the compound to diffuse and permeate include water, and a compound having a polar group such as a hydroxyl group, a carboxyl group, a ketone group, an aldehydes group or an ester group. The boiling point of these compounds is preferably not more than 200° C., more preferably not more than 150° C., and preferably not less than 50° C., more preferably not less than 70° C. The molecular weight is preferably not more than 150, and more preferably not more than 100.

The permeation of water is preferably carried out at high humidity. The permeation of water is carried out at ordinarily not less than 0.007 kg/kg′, preferably not less than 0.018 kg/kg′, and preferably not more than 0.5 kg/kg′, and more preferably not more than 0.2 kg/kg′ in terms of absolute humidity for preferably not less than 10 hours, and more preferably from 16 to 32 hours. In order to control the humidity accurately, the permeation of water is carried out at a temperature of preferably not less than 30° C., more preferably not less than 40° C., and preferably not more than 100° C., more preferably not more than 80° C., and still more preferably not more than 60° C. The residual solvent content of the image formation layer after aging treatment is preferably not more than 8% by weight, more preferably not more than 6% by weight, and still more preferably not more than 7% by weight, and preferably not less than 0.05% by weight, and more preferably 0.2% by weight.

### (Surfactants)

In the invention, the upper and/or lower layer can contain non-ionic surfactants as disclosed in Japanese Patent O.P.I. Publication Nos. 62-251740 and 3-208514, amphoteric surfactants as disclosed in Japanese Patent O.P.I. Publication Nos. 59-121044 and 4-13149, siloxane compounds disclosed in EP 950517, or fluorine-containing copolymers disclosed in Japanese Patent O.P.I. Publication Nos. 62-170950, 11-288093, and 2003-57820, in order to improve the coatability and increase stability under various developing conditions.

Examples of the non-ionic surfactants include sorbitan tristearate, sorbitan monopalmitate, sorbitan trioleate, stearic acid monoglyceride, polyoxyethylene sorbitan monooleate, and polyoxyethylene nonylphenyl ether. Examples of the amphoteric surfactants include alkyldi(aminoethyl)-glycine, alkylpoly(aminoethyl)glycine hydrochloride, 2-alkyl-N-carboxyethyl-N-hydroxyethylimidazolinium betaine, and N-tetradecyl-N,N-betaine type compounds (for example, trade name: AMOGEN K produced by DAIICHI KOGYO CO., LTD.).

Examples of the siloxane compounds include a block copolymer of dimethyl polysiloxane and polyalkylene oxide, for example, polyalkylene oxide-modified silicons such as DBE-224, DBE-621, DBE-712, DBE-732, and DBE-534, each produced by Chisso Co., Ltd., and Tego Glide 100 produced by Tego Co., Ltd. The surfactant content of the upper or lower layer is preferably from 0.01 to 15% by weight, and more preferably from 0.1 to 5% by weight.

### <Exposure and Development>>

The above-obtained planographic printing plate material is ordinarily imagewise exposed and developed to prepare a planographic printing plate for printing.

A light source employed for imagewise exposure is preferably one having an emission wavelength in the wavelength regions of from near infrared to infrared, and more preferably a solid laser or a semiconductor laser. Imagewise exposure is carried out through an infrared laser (830 nm) based on digital converted data, employing a setter for CTP available on the market, followed by development, whereby a planographic printing plate with an image on the aluminum support used for printing is obtained.

An exposure device used in the invention is not specifically limited, as long as it is a laser method. Any of a method of laser scanning on an outer surface of a drum (an outer drum scanning method), a method of laser scanning on an inner surface of a drum (an inner drum scanning method), and a method of laser scanning on a plane (a flat head scanning method) can be used. The outer drum scanning method is preferably used which can easily provide multi-beams for improving productivity of low exposure intensity and long time exposure. An exposure device with a GLV modulation element employing the outer drum scanning method is especially preferred.

In the invention, a laser beam pixel dwell time means time in which a laser beam scans one pixel (one dot), i.e., exposure time per pixel. In the invention, the laser beam pixel dwell time is preferably from 2.0 to 20 microseconds, and more preferably from 2.5 to 15 microseconds. The laser beam intensity at time when the laser beam scans one pixel is preferably from 10 to 300 mJ/cm², and more preferably from 30 to 180 mJ/cm².

It is preferred in the invention that imagewise exposure is carried out employing an exposure device with a GLV modulation element whereby laser beams are multi-channeled, which improves productivity of planographic printing plates.

The GLV modulation element is preferably one capable of dividing laser beams into not less than 200 channels, and more preferably one capable of dividing laser beams into not less than 500 channels. The laser beam spot diameter is preferably not more than 15 μm, and more preferably not more than 10 μm. The laser output power is preferably from 10 to 100 W, and more preferably from 20 to 80 W. The drum rotation number is preferably from 20 to 300 rpm, and more preferably from 30 to 200 rpm.

### (Developer)

A developer or developer replenisher applicable to the planographic printing plate material of the invention is one having a pH of from 9.0 to 14.0, and preferably from 12.0 to 13.5. A developer including a developer replenisher (hereinafter also referred to as simply a developer) in the invention is a well known aqueous alkaline solution containing, as an alkali agent, sodium hydroxide, ammonium hydroxide, potassium hydroxide or lithium hydroxide. These alkali agents may be used singly or as an admixture of two or more kinds thereof.

Other alkali agents include potassium silicate, sodium silicate, lithium silicate, ammonium silicate, potassium metasilicate, sodium metasilicate, lithium metasilicate, ammonium metasilicate, potassium phosphate, sodium phosphate, lithium phosphate, ammonium phosphate, potassium hydrogenphosphate, sodium hydrogenphosphate, lithium hydrogenphosphate, ammonium hydrogenphosphate, potassium carbonate, sodium carbonate, lithium carbonate, ammonium carbonate, potassium hydrogencarbonate, sodium hydrogencarbonate, lithium hydrogencarbonate, ammonium hydrogencarbonate, potassium borate, sodium borate, lithium borate and ammonium borate. Sodium hydroxide, ammonium hydroxide, potassium hydroxide or lithium hydroxide may be added to developer in order to adjust the pH of developer.

An organic alkali agent such as monomethylamine, dimethylamine, trimethylamine, monoethylamine, diethylamine, triethylamine, monoisobutylamine, diisobutylamine, triisobutylamine, n-butylamine, monoethanolamine, diethanolamine, triethanolamine, monoisopropanolamine, diisopropanolamine, ethyleneimine, ethylenediamine or pyridine can be used in combination.

Among these, potassium silicate or sodium silicate is preferred. The concentration of silicate in the developer is preferably from 2 to 4% by weight in terms of SiO₂ concentration. The ratio by mole (SiO₂/M) of SiO₂ to alkali metal M is preferably from 0.25 to 2.

The developer in the invention refers to a developer (so-called working developer) replenished with developer replenisher in order to maintain activity of the developer which lowers during development of light sensitive planographic printing plate material, as well as fresh developer used at the beginning of development.

The developer or developer replenisher in the invention can contain various surfactants or organic solvents as necessary, in order to accelerate development, disperse smuts occurring during development, or enhance ink receptivity at image portions of printing plate.

Preferred examples of the nonionic surfactant include polyoxyethylenealkyl ethers, polyoxyethylenealkylphenyl ethers, polyoxyethylene-polystyrylphenyl ethers, polyoxyethylenepolyoxypropylenalkyl ethers, partial esters of glycerin and fatty acids, partial esters of sorbitan and fatty acids, partial esters of pentaerythritol and fatty acids, propylene glycol monofatty acid ester, partial esters of sucrose and fatty acids, partial esters of polyoxyethylenesorbitan and fatty acids, partial esters of polyoxyethylenesorbitol and fatty acids, esters of polyoxyethylene glycol and fatty acids, partial esters of polyglycerin and fatty acids, polyoxyethylene castor oil, partial esters of polyoxyethyleneglycerin and fatty acids, polyoxyethylene-polyoxypropylene block copolymer, adduct of polyoxyethylene-polyoxypropylene block copolymer with ethylene imine, fatty acid diethanolamides, N,N-bis-2-hydroxyalkylamines, polyoxyethylenealkylamines, triethanolamine fatty acid esters, and trialkylamine oxides. Examples of the anionic surfactant include fatty acid salts, abietic acid salts, hydroxyalkane sulfonic acid salts, alkane sulfonic acid salts, dialkylsulfosuccinic acid salts, straight-chained alkylbenzene sulfonic acid salts, branched alkylbenzene sulfonic acid salts, alkylnaphthalene sulfonic acid salts, alkyldiphenylether sulfonic acid salts, alkylphenoxypolyoxyethylenepropyl sulfonic acid salts, polyoxyethylenealkyl sulfophenylether salts, N-methyl-N-oleiltaurine sodium salts, N-alkylsulfosuccinic acid monoamide disodium salts, petroleum sulfonic acid salts, nitrated castor oil, sulfated beef tallow, fatty acid alkyl ester sulfate salts, alkylsulfate salts, polyoxyethylenealkylethersulfate salts, fatty acid monoglyceride sulfate salts, polyoxyethylenealkylphenylethersulfate salts, polyoxyethylenestyrylphenylethersulfate salts, alkylphosphate salts, polyoxyethylenealkyletherphosphate salts, polyoxyethylenealkylphenyletherphosphate salts, partial saponification products of styrene-maleic anhydride copolymers, partial saponification products of olefin-maleic anhydride copolymers, and condensates of naphthalene sulfonic acid salts with formalin. Examples of the cationic surfactant include alkylamine salts, quaternary ammonium salts such as tetrabutylammonium bromide, polyoxyethylene alkylamine salts, and polyethylene polyamine derivatives. Examples of the amphoteric surfactant include carboxybetains, amino carboxylic acids, sulfobetaines, aminosulfates and imidazolines.

Surfactants, in which the polyoxyethylene in the surfactants described above is replaced by polyoxypropylene or polyoxybutylene can be also used. A preferred surfactant is a fluorine-containing surfactant having a perfluoroalkyl group in the molecule.

Examples thereof include anionic ones such as perfluoroalkyl carboxylic acid salts, perfluoroalkyl sulfonic acid salts, and perfluoroalkyl phosphates; amphoteric ones such as perfluoroalkyl betaines; cationic ones such as perfluoroalkyltrimethylammonium salts; and nonionic ones such as perfluoroalkylamineoxide, perfluoroalkylethylene oxide adduct, an oligomer having a perfluoroalkyl group and a hydrophilic group, an oligomer having a perfluoroalkyl group and an oleophilic group, an oligomer having a perfluoroalkyl group, a hydrophilic group and an oleophilic group, and urethanes having a perfluoroalkyl group or an oleophilic group. These surfactants may be used singly or as an admixture of two or more kinds thereof. The surfactant content of the developer is preferably from 0.001 to 10% by weight, and more preferably from 0.01 to 5% by weight.

The developer or developer replenisher can contain a development stabilizing agent if necessary. The preferred examples of the development stabilizing agent include an adduct of sugar alcohol with polyethylene glycol, tetraalkylammonium hydroxide such as tetrabutylammonium hydroxide, a phosphonium salt such as tetrabutylphosphonium bromide, and an iodonium salt such as diphenyliodonium chloride, as disclosed in Japanese Patent O.P.I. Publication No. 6-282079.

Examples of the development stabilizing agent include anionic surfactants or amphoteric surfactants disclosed in Japanese Patent O.P.I. Publication No. 50-51324, water soluble cationic polymers disclosed in Japanese Patent O.P.I. Publication No. 55-95946, and water soluble amphoteric surfactants disclosed in Japanese Patent O.P.I. Publication No. 56-142528. Further, the examples include organic boron-containing compound to which alkylene glycol is added, disclosed in Japanese Patent O.P.I. Publication No. 59-84241, polyoxyethylene-polyoxypropylene block polymer type water-soluble surfactant, disclosed in Japanese Patent O.P.I. Publication No. 60-111264, an alkylenediamine compound having polyoxyethylene-polyoxypropylene, disclosed in Japanese Patent O.P.I. Publication No. 60-129750, polyoxyethylene, glycol with an average weight molecular weight of not less than 300 disclosed in Japanese Patent O.P.I. Publication No. 61-215554, a fluorine-containing surfactant having a cationic group disclosed in Japanese Patent O.P.I. Publication No. 63-175858, and a water soluble ethyleneoxide adduct obtained by adding ethyleneoxy to an acid or an alcohol, or water soluble polyalkylenes disclosed in Japanese Patent O.P.I. Publication No. 2-39157.

Organic solvents are optionally added to the developer or the developer replenisher. The organic solvent is a solvent having a solubility in water of suitably 10 weight % or less, and preferably 5 weight % or less. Examples of the organic solvent include 1-phenylethanol, 2-phenylethanol, 3-phenyl-1-propanol, 4-phenyl-1-butanol, 1-phenyl-2-butanol, 2-phonoxyethanol, 2-benzyloxyethanol, o-methoxybenzylalcohol, m-methoxybenzylalcohol, p-methoxybenzylalcohol, benzylalcohol, cyclohexanol, 2-methylcyclohexanol, 3-methylcyclohexanol, 4-methylcyclohexanol, N-phenylethanolamine, and N-phenyldiethanolamine.

The organic solvent content of the working developer is preferably 0.1 to 5 weight %. It is preferred that the organic solvent content is not substantially contained in the developer or developer replenisher. The term “not substantially contained” means that the organic solvent is contained in an amount of not more than 1% by weight.

An organic carboxylic acid is optionally added to the developer or the developer replenisher. Preferred organic carboxylic acids include an aliphatic carboxylic acid or an aromatic carboxylic acid each having a carbon atom number of from 6 to 20.

Examples of the aliphatic carboxylic acid include caproic acid, enanthic acid, caprylic acid, lauric acid, myristic acid, palmitic acid, and stearic acid. Particularly preferred are alkanoic acids having a carbon atom number of from 8 to 12. The acid may be an unsaturated acid having a double bond in the molecule or may have a branched carbon chain.

The aromatic carboxylic acid is an aromatic compound such as benzene, naphthalene or anthracene having a carboxyl group. Examples of the aromatic carboxylic acid include o-chlorobenzoic acid, p-chlorobenzoic acid, o-hydroxybenzoic acid, p-hydroxybenzoic acid, o-aminobenzoic acid, p-aminobenzoic acid, 2,4-dihydroxybenzoic acid, 2,5-dihydroxybenzoic acid, 2,6-dihydroxybenzoic acid, 2,3-dihydroxybenzoic acid, 3,5-dihydroxybenzoic acid, gallic acid, 1-hydroxy-2-naphthoic acid, 3-hydroxy-2-naphthoic acid, 2-hydroxy-1-naphthoic acid, 1-naphthoic acid, and 2-naphthoic acid. Hydroxy naphthoic acids are especially preferred.

These carboxylic acids are preferably used in the salt form, for example as the sodium salts, potassium salts or ammonium salts, in order to increase their water solubility. The organic carboxylic acid content of the developer is not specifically limited, but the content lass than 0.1% by weight does not exhibit advantageous effects, while the content exceeding 10% by weight cannot enhance the effects and may prevent dissolution of other additives into the developer. Therefore, the organic carboxylic acid content of the working developer is preferably from 0.1 to 10% by weight, and more preferably from 0.5 to 4% by weight.

The developer or developer replenisher may contain the following additives in order to increase development performance. Examples of the additives include a neutral salt such as sodium chloride, potassium chloride, potassium bromide, as disclosed in Japanese Patent O.P.I. Publication No. 58-75152, a complex such as [Co(NH₃)₆]Cl₃ as disclosed in Japanese Patent O.P.I. Publication No. 59-121336, an amphoteric polymer such as a copolymer of vinylbenzyl-trimethylammonium chloride and sodium acrylate as disclosed in Japanese Patent O.P.I. Publication No. 56-142258, the organic metal containing surfactant containing Si or Ti as disclosed in Japanese Patent O.P.I. Publication No. 59-75255, and the organic boron containing compound disclosed in Japanese Patent O.P.I. Publication No. 59-84241.

The developer or developer replenisher in the invention can further contain an antiseptic agent, a coloring agent, a viscosity increasing agent, an antifoaming agent, or a water softener. Examples of the antifoaming agent include mineral oil, vegetable oil, alcohols, surfactants, and silicon oil disclosed in Japanese Patent O.P.I. Publication No. 2-244143.

The water softeners include polyphosphoric acid or its sodium, potassium or ammonium salt; aminopolycarboxylic acids or their salts such as ethylenediaminetetraacetic acid or its sodium, potassium or ammonium salt, diethylenetriaminepentaacetic acid or its sodium, potassium or ammonium salt, triethylenetetramine-hexaacetic acid or its sodium, potassium or ammonium salt, hydroxyethylethylene-diaminetriacetic acid or its sodium, potassium or ammonium salt, nitrilotriacetic acid or its sodium, potassium or ammonium salt, 1,2-diaminocyclohexane-tetraacetic acid or its sodium, potassium or ammonium salt, 1,3-diamino-2-propanoltetraacetic acid or its sodium, potassium or ammonium salt; and phosphonic acids or their salts such as aminotri(methylenephosphonic acid) or its sodium, potassium or ammonium salt, ethylenediaminetetra-(methylenephosphonic acid) or its sodium, potassium or ammonium salt, diethylenetriaminepenta(methylenephosphonic acid) or its sodium, potassium or ammonium salt, triethylenetetraminehexa(methylenephosphonic acid) or its sodium, potassium or ammonium salt, hydroxyethyl-ethylenediaminetri(methylenephosphonic acid) or its sodium, potassium or ammonium salt, and 1-hydroxyethane-1,1-diphosphonic acid or its sodium, potassium or ammonium salt.

The water softener content of the developer varies on hardness or amount of a hard water used, but the content is preferably 0.01 to 5 weight %, and more preferably 0.01 to 0.5 weight %. The content less than the above range cannot attain the desired objects while the content exceeding the above range has an adverse effect on image areas such as dye elimination.

The developer or developer replenisher is prepared by dissolving the components described above in water.

The developer or developer replenisher used in the invention is an aqueous concentrated solution with a low water content, which is diluted with water and used for development. The aqueous concentrated solution is advantageous in view of its transport. The degree of concentration of the concentrated solution is such that the components contained in the solution are not separated nor precipitated. The concentrated solution may contain a solubilizing agent. As the solubilizing agent is preferred so-called a hydrotrope such as toluene sulfonic acid, xylene sulfonic acid, or their alkali metal salt, which is disclosed in Japanese Patent O.P.I. Publication Nos. 6-32081.

### (Non-Silicate Developer)

Development of the planographic printing plate material of the invention can be also carried out employing a so-called “non-silicate developer” containing a non-reducing saccharide and a base but containing no alkali silicate. Development of the planographic printing plate material employing this developer provides a recording layer with good ink receptivity at the image portions without deteriorating the recording layer surface. Generally, development latitude of a planographic printing plate material is narrow, and the line width of line images of a developed planographic printing plate material is greatly changed due to pH of developer. Since the non-silicate developer contains a non-reducing saccharide with buffering property restraining a pH change, it is more advantageous than a developer containing a silicate. The non-silicate developer is also advantageous, since the non-reducing saccharide makes it difficult to contaminate an electrical conductivity sensor, a pH sensor, and the like controlling the activity of a developer, compared with a silicate. Further, the non-silicate developer greatly improves discrimination between the image and non-image portions.

The non-reducing saccharide is one having neither aldehyde group nor ketone group and exhibiting no reducing power. The saccharide is classified into trehalose type oligosaccharide, in which the reducing groups are bonded to each other; glycoside, in which a reducing group of a saccharide is bonded to a non-saccharide; and saccharide alcohol obtained by reducing a saccharide by hydrogenation. In the invention, any one of these saccharides is preferably used. In the invention, non-reducing saccharides disclosed in Japanese Patent O.P.I. Publication No. 8-305039 can be suitably used.

These no-reducing saccharides may be used singly or as an admixture of two or more kinds thereof. The no-reducing saccharide content of the non-silicate developer is preferably from 0.1 to 30% by weight, and more preferably from 1 to 20% by weight, in view of availability and easiness of concentration.

It is advantageous that an automatic developing machine is used in order to develop a light sensitive planographic printing plate material. It is preferred that the automatic developing machine is equipped with a means for automatically introducing a developer replenisher in a necessary amount into a developing bath, a means for discharging any excessive developer and a means for automatically introducing water in necessary amounts to the developing bath. It is preferred that the automatic developing machine comprises a means for detecting a planographic printing plate material to be transported, a means for calculating the area to be processed of the planographic printing plate material based on the detection, or a means for controlling a replenishing amount of a developer replenisher, a replenishing amount of water to be replenished or replenishing timing based on the detection and calculation. It is also preferred that the automatic developing machine comprises a means for controlling a temperature of a developer, a means for detecting a pH and/or electric conductivity of a developer, or a means for controlling a replenishing amount of the developer replenisher, a replenishing amount of water to be replenished and/or the replenishing timing based on the detected pH and/or electric conductivity.

The automatic developing machine used in the invention may be provided with a pre-processing section to allow the plate to be immersed in a pre-processing solution prior to development. The pre-processing section is provided preferably with a mechanism of spraying a pre-processing solution onto the plate surface, preferably with a mechanism of controlling the pre-processing solution at a temperature within the range of 25 to 55° C., and preferably with a mechanism of rubbing the plate surface with a roller-type brush. Common water and the like are employed as the pre-processing solution.

The planographic printing plate material exposed and developed with the developer is preferably subjected to post-processing. The post-processing comprises the step of processing the developed planographic printing plate material with a post-processing solution such as washing water, a rinsing solution containing a surfactant, a finisher or a protective gumming solution containing gum arabic or starch derivatives as a main component. The post-processing is carried out employing an appropriate combination of the post-processing solutions described above. For example, a method is preferred in which the developed planographic printing plate material is post-washed with washing water, and then processed with a rinsing solution containing a surfactant, or a developed planographic printing plate precursor is post-washed with washing water, and then processed with a finisher, since it reduces fatigue of the rinsing solution or the finisher.

It is preferred that a multi-step countercurrent processing is carried out employing a rinsing solution or a finisher. The post-processing is carried out employing an automatic developing machine having a development section and a post-processing section.

In the post-processing step, the developed printing plate is sprayed with the post-processing solution from a spray nozzle or is immersed into the post-processing solution in a post-processing tank. A method is known in which supplies a small amount of water onto the developed printing plate precursor to wash the precursor, and reuses the water used for washing as dilution water for developer concentrate. In the automatic developing machine, a method is applied in which each processing solution is replenished with the respective processing replenisher according to the area of the printing plate precursor to have been processed or the operating time of the machine.

A method (use-and-discard method) can be applied in which the developed printing plate material is processed with fresh processing solution and discarded. The thus obtained planographic printing plate is mounted on a printing press, and printing is carried out.

### (Erasing)

When there are unnecessary images (for example, images resulting from the edges of an original used) in the printing plate obtained by imagewise exposing, developing, washing with water, and/or optionally rinsing and/or gumming, the planographic printing plate material of the invention, the images are erased. It is preferred that the erasing is carried out according to a method disclosed in Japanese Patent Publication No. 2-13293 and Japanese Patent O.P.I. Publication Nos. 10-186679, 2003-122026, and 2005-221961, in which an erasing liquid is coated on the unnecessary images, allowed to stand for a while, and then washed with water to remove them. A method disclosed in Japanese Patent O.P.I. Publication Nos. 59-174842 can be also used, in which the unnecessary images are exposed to actinic rays from an optical fiber, and then developed.

### (Burning Treatment)

The planographic printing plate obtained above is subjected to burning treatment in order to obtain a printing plate with high printing durability.

When the planographic printing plate is subjected to burning treatment, it is preferred that prior to the burning treatment, the printing plate is surface-processed with a cleaning solution disclosed in Japanese Patent Publication Nos. 61-2518 and 55-28062, and Japanese Patent O.P.I. Publication Nos. 62-31859 and 61-159655.

As the surface-processing method, there is a method coating the cleaning solution on the planographic printing plate, employing a sponge or absorbent cotton impregnated with the cleaning solution, a method immersing the planographic printing plate in the vessel charged with the cleaning solution or a method coating the cleaning solution on the planographic printing plate employing an automatic coater. It is preferred that the coated cleaning solution is squeegeed with for example, a squeegee roller to give uniform coating.

The coating amount of the cleaning solution is ordinarily from 0.03 to 0.8 g/m², in terms of dry coating amount. If necessary, a planographic printing plate coated with the cleaning solution is dried and heated to high temperature, employing a burning processor (for example, a burning processor BP-1300, available from Fuji Photo Film Co., Ltd.). The heating temperature is preferably from 180 to 300° C., and the heating period is preferably from 1 to 20 minutes, although they are different due to kinds of components forming an image.

A planographic printing plate subjected to burning treatment can be subjected to conventional processing such as water washing or gumming, if necessary, but when the cleaning solution containing a water-soluble polymer is used, desensitizing treatment such as gumming can be eliminated. The thus obtained planographic printing plate is mounted on a printing press, followed by printing, whereby many prints are obtained.

### (Packaging Material)

### [Interleaf]

An interleaf is preferably inserted between the two of the planographic printing plate materials of the invention, in order to prevent physical impact to the planographic printing plate material during storage or to minimize undesired impact during transportation. The interleaf is selected from many kinds thereof.

As an interleaf, one, which is manufactured employing inexpensive materials, is often used in order to reduce material cost. Examples thereof include a paper sheet comprised of 100% wood pulp, a paper sheet comprised of wood pulp and synthetic pulp, and a paper sheet in which a low or high density polyethylene film is provided on the paper sheet comprised of 100% wood pulp or the paper sheet comprised of wood pulp and synthetic pulp. A paper sheet, which does not employ synthetic pulp or polyethylene film can be manufactured at low cost, since the material cost is low.

A preferred interleaf is one having a basis weight of from 30 to 60 g/m², a smoothness of from 10 to 100 seconds, the smoothness measured according to a Bekk smoothness measuring method described in JIS 8119, a moisture content of from 4 to 8%, the moisture content measured according to a moisture content measuring method described in JIS 8127, and a density of from 0.7 to 0.9 g/cm³. An interleaf is preferably one in which a polymer film is not laminated on the surface facing the light sensitive layer, in order to absorb the residual solvents.

Printing is carried out employing a conventional printing press.

In recent years, printing ink containing no petroleum volatile organic compound (VOC) has been developed and used in view of environmental concern. The present invention provides excellent effects in employing such a printing ink.

Examples of such a printing ink include soybean oil ink “Naturalith 100” produced by Dainippon Ink Kagaku Kogyo Co., Ltd., VOC zero ink “TK HIGH ECO NV” produced by Toyo Ink Manufacturing Co., Ltd., and process ink “Soycelvo” produced by Tokyo Ink Co., Ltd.

### EXAMPLES

The present invention will be explained in detail below employing examples, but is not limited thereto. In the examples, “parts” is “parts by weight”, unless otherwise specified.

### [Preparation of Support]

### (Preparation of Aluminum Support)

A 0.24 mm thick aluminum plate (material 1050, refining H16) was immersed in an aqueous 5% by weight sodium hydroxide solution at 50° C. to give an aluminum dissolution amount of 2 g/m², washed with water, immersed in an aqueous 10% by weight nitric acid solution at 25° C. for 30 seconds to neutralize, and then washed with water.

Subsequently, the aluminum plate was subjected to electrolytic surface-roughening treatment in an electrolytic solution containing 10 g/liter of hydrochloric acid and 0.5 g/liter of aluminum at a current density of 60 A/dm² employing an alternating current with a sine waveform, in which the distance between the plate surface and the electrode was 10 mm. The electrolytic surface-roughening treatment was divided into 12 treatments, in which the quantity of electricity used in one treatment (at anodic time) was 80 C/dm², and the total quantity of electricity used (at anodic time) was 960 C/dm². Standby time of 1 second, during which no surface-roughening treatment was carried out, was provided after each of the separate electrolytic surface-roughening treatments.

Subsequently, the resulting aluminum plate was immersed in an aqueous 10% by weight phosphoric acid solution at 50° C. and etched to give an aluminum etching amount (including smut produced on the surface) of 1.2 g/m², and washed with water. Subsequently, the aluminum plate was subjected to anodizing treatment in an aqueous 20% by weight sulfuric acid solution at a quantity of electricity of 250 C/dm² under a constant voltage of 20V, and washed with water. The aluminum plate surface was squeegeed to remove the residual water on the surface, and the plate was immersed in an aqueous 2% by weight sodium silicate No. 3 solution at 85° C. for 30 seconds, washed with water, then immersed in an aqueous 0.4% by weight polyvinyl phosphonic acid (hereinafter referred to as PVPA) solution at 60° C. for 30 seconds, and washed with water. The aluminum plate surface being squeegeed, the aluminum plate was subjected to heating treatment at 130° C. for 50 seconds. Thus, an aluminum support was obtained.

The surface roughness Ra of the aluminum support obtained above was 0.55 μm, measured through SE 1700a (available from Kosaka Kenkyusho Co., Ltd.). The support surface being observed through an SEM by a factor of 100000, the pore diameter of the anodization film was 40 nm. The polyvinyl phosphonic acid layer had a thickness of 0.01 μm.

### (Preparation of Planographic Printing Plate Material Samples)

The following lower light sensitive layer coating solution was coated on the Support 1, employing a wire bar and dried at 120° C. for 1 minute to give a lower light sensitive layer with a dry coating amount of 1.0 g/m². The following upper light sensitive layer coating solution was coated on the resulting lower layer, employing a wire bar and dried at 120° C. for 1.5 minutes to give an upper light sensitive layer with a dry coating amount of 0.4 g/m². The resulting coating material was cut into a size of 600×400 mm, and 200 sheets thereof were stacked, an interleaf P inserted between the two nearest sheets, and was subjected to aging treatment for 24 hours at 45° C. and at absolute humidity of 0.037 kg/kg′. Thus, a planographic printing plate material sample 9 was prepared.

### (Preparation of Interleaf P)

A rosin sizing agent was added to the paper stock solution having a 4% concentration of bleached kraft pulp to have a rosin sizing agent content of 0.4%, and aluminum sulfate was added thereto to give a pH of 5. Thereafter, a reinforcing agent comprised mainly of starch was added to give a reinforcing agent content of 5.0% by weight. Interleaf P with a basis weight of 40 g/m² and a moisture content of 0.5% was prepared from the resulting solution.

### (Lower Light Sensitive Layer Coating Solution)

| | |
|---|---|
| Acryl resin 1 (described below) | 78.0 parts |
| Infrared absorbing dye Dye 1 (described below) | 6.0 parts |
| Crystal violet dye | 0.8 parts |
| (produced by Hodogaya Kagaku Co., Ltd.) | |
| Acid decomposable compound A | 1.0 part |
| (described previously) | |
| Acid decomposable compound B | 5.0 parts |
| (described previously) | |
| Acid generating agent BR22 (described below) | 2.0 part |
| Fluorine-containing surfactant | 0.3 parts |
| Megafac F178K (produced by Dainippon Ink | |
| & Chemicals Inc.) | |
| Exemplified Pigment A (described previously) | 5.0 parts |
| (Pigment having on the surface a development | |
| restrainer) | |
| Solvent: γ-butyrolactone/methyl ethyl | 901.9 parts |
| ketone/1-methoxy-2- | |
| propanol (1/2/1) | |
| (Upper Light Sensitive Layer Coating Solution) | |
| Cresol novolak resin | 65.0 parts |
| (m/p = 7/3, molecular weight: 5000) | |
| Acryl resin 1 (described below) | 23.0 parts |
| Infrared absorbing dye (Dye 1) | 6.0 parts |
| (described below) | |
| Fluorine-containing surfactant | 1.0 part |
| Megafac F178K (produced by Dainippon | |
| Ink & Chemicals Inc.) | |
| Solvent: methyl ethyl ketone/1-methoxy-2- | 905.0 parts |
| propanol (1/2) | |

Dye 1

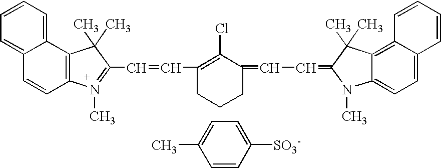

Acryl resin 1

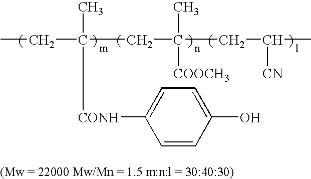

BR22

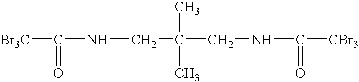

A planographic printing plate material sample 1 was prepared in the same manner as planographic printing plate material sample 9, except that none of Acid decomposable compounds A and B and Acid generating agent BR22 were used in the lower layer. A planographic printing plate material sample 2 was prepared in the same manner as planographic printing plate material sample 9, except that none of Acid decomposable compounds A and B, Acid generating agent BR22 and Pigment A were used in the lower layer. A planographic printing plate material sample 3 was prepared in the same manner as planographic printing plate material sample 9, except that the upper layer was not provided and Pigment A was not used in the lower layer. A planographic printing plate material sample 4 was prepared in the same manner as planographic printing plate material sample 9, except that CB1 was used instead of Pigment A in the lower layer. A planographic printing plate material sample 5 was prepared in the same manner as planographic printing plate material sample 9, except that CB2 was used instead of Pigment A in the lower layer. A planographic printing plate material sample 6 was prepared in the same manner as planographic printing plate material sample 9, except that CBP was used instead of Pigment A in the lower layer. A planographic printing plate material sample 7 was prepared in the same manner as planographic printing plate material sample 9, except that the upper layer was not provided. A planographic printing plate material sample 8 was prepared in the same manner as planographic printing plate material sample 9, except that none of Acid decomposable compounds A and B and Acid generating agent BR22 were used in the lower layer. A planographic printing plate material sample 10 was prepared in the same manner as planographic printing plate material sample 9, except that Pigment A was added to the upper layer in an amount of 5.0 parts by weight and Pigment A was not used in the lower layer. A planographic printing plate material sample 11 was prepared in the same manner as planographic printing plate material sample 9, except that Pigment B was used instead of Pigment A in the lower layer. A planographic printing plate material sample 12 was prepared in the same manner as planographic printing plate material sample 9, except that Pigment C was used instead of Pigment A in the lower layer.

### (Exposure and Development)

Employing PTR-4300 (manufactured by Dainippon Screen Manufacturing Co., Ltd.), each of the resulting planographic printing plate material samples was imagewise exposed at a drum rotation number of 1000 rpm and at a resolution of 2400 dpi while the laser output power was changed from 30% to 100% to form a dot image with a screen line number of 175 lines.

Employing an automatic developing machine Raptor 85 Thermal (available from GLUNZ & JENSEN Co., Ltd.), the exposed sample was developed with a developer PD1 (available from Kodak Polychrome Graphics Co., Ltd.) at 30° C. for 15 seconds. Thus, a planographic printing plate sample was obtained.

### <Evaluation>

### (Sensitivity)

The printing plate material sample was exposed while varying laser light exposure energy, and developed in the same manner as above to obtain solid image portions and non-image portions. The optical density of the resulting non-image portions was measured through a densitometer D196 (produced by GRETAG Co., Ltd.). The exposure energy providing an optical density of the support (uncoated) surface optical density plus 0.01 was determined and defined as sensitivity.

### Scratch Resistance

The surface of the sample obtained above was scratched with a sapphire needle having a tip diameter of 0.1 mm through a scratch tester Heidon-18 produced by Heidon Co., Ltd., load, the weight changed from 1 to 20 g at an interval of 1 g, being applied to the sapphire needle. The scratched sample was developed with the developer as described, and the scratched portions were observed. A minimum load (g) at which the layer was peeled from the support was observed. The more the minimum load is, the higher the scratch resistance.

### (Development Latitude)

Employing PTR-4300 (manufactured by Dainippon Screen Manufacturing Co., Ltd.), each of the resulting positive working planographic printing plate material samples was imagewise exposed at exposure energy providing its sensitivity, at a drum rotation number of 1000 rpm and at a resolution of 2400 dpi to form a dot image with a screen line number of 175 lines.

Employing an automatic developing machine Raptor 85 Thermal (available from GLUNZ & JENSEN Co., Ltd.), the exposed sample was developed with a developer PD1 (available from Kodak Polychrome Graphics Co., Ltd.) at 30° C. Thus, a planographic printing plate sample was obtained.

In the planographic printing plate sample obtained above, contamination due to a residual layer at non-image portions or layer reduction at image portions, which resulted from development fault, was observed at a magnification of 50 by a magnifier. Developing time range during which satisfactory development was carried out without contamination or layer reduction was determined as a measure of development latitude.

### (Safelight Property)

The planographic printing plate sample obtained above was exposed to a white fluorescent lamp at an illuminance of 300 LX for a certain period, and developed in the same manner as described above. The minimum developing time (minutes) at which the light sensitive layer was completely removed was determined and evaluated as a measure of safelight property. The longer the time is, the higher the safelight property.

The results are shown in Table 1.

TABLE 1

| | | | Lower Layer | | | |
|---|---|---|---|---|---|---|
| | Light | Upper | Acid | Acid | | |
| | Sensitive | Layer | Decomposable | Generating | | |
| Sample | Layer | Pigment | Compound | Agent | Pigment | |
| No. | Structure | used | used | used | used | Remarks |
| 1 | Two Layers | None | A & B | BR22 | None | Comp. |
| 2 | Two Layers | None | None | None | None | Comp. |
| 3 | Single Layer | — | A & B | BR22 | None | Comp. |
| 4 | Two Layers | None | A & B | BR22 | CB 1 | Comp. |
| 5 | Two Layers | None | A & B | BR22 | CB 2 | Comp. |
| 6 | Two Layers | None | A & B | BR22 | CBP | Comp. |
| 7 | Single Layer | — | A & B | BR22 | Pig. A | Inv. |
| 8 | Two Layers | None | None | None | Pig. A | Inv. |
| 9 | Two Layers | None | A & B | BR22 | Pig. A | Inv. |
| 10 | Two Layers | Pig. A | A & B | BR22 | None | Inv. |
| 11 | Two Layers | None | A & B | BR22 | Pig. B | Inv. |
| 12 | Two Layers | None | A & B | BR22 | Pig. C | Inv. |

| | | Development | Safelight | Scratch | |
|---|---|---|---|---|---|
| Sample | Sensitivity | Latitude | Property | Resistance | |
| No. | (mJ/cm²) | (sec.) | (min.) | (g) | Remarks |
| 1 | 200 | 25 | 25 | 2 | Comp. |
| 2 | 300 | 10 | 120 | 1 | Comp. |
| 3 | 320 | 15 | 30 | 2 | Comp. |
| 4 | 180 | 20 | 50 | 1 | Comp. |
| 5 | 170 | 30 | 30 | 1 | Comp. |
| 6 | 210 | 30 | 45 | 1 | Comp. |
| 7 | 150 | 45 | 150 | 4 | Inv. |
| 8 | 160 | 50 | 260 | 3 | Inv. |
| 9 | 100 | 75 | 300 | 4 | Inv. |
| 10 | 180 | 40 | 300 | 3 | Inv. |
| 11 | 110 | 60 | 220 | 3 | Inv. |
| 12 | 90 | 70 | 350 | 4 | Inv. |

Comp.: Comparative,
Inv.: Inventive
A: Acid decomposable compound A
B: Acid decomposable compound B
CB 1: Carbon Black #4300 (not surface-modified) (produced by Tokai Carbon Co. Ltd.)
CB 2: Carbon Black AQUA-BLACK001 (surface-modified with a hydroxyl group-containing compound) (produced by Tokai Carbon Co. Ltd.)
CBP: Cyanine Blue 4937 (available from Dainichiseika Color & Chemicals Mfg. Co., Ltd.)
Pig. A: Exemplified Pigment A
Pig. B: Pigment B prepared in the same manner as Exemplified Pigment A, except that Cyanine Blue 4937 was used instead of carbon black, and polyethylene glycol (with a molecular weight of 400) was used instead of diethanolamine
Pig. C: Pigment C prepared in the same manner as Pigment B, except that CB 2 was used instead of Cyanine Blue 4937

As is apparent from Table 1, the inventive planographic printing plate samples are excellent in any of sensitivity, development latitude, safelight property and scratch resistance, as compared with the comparative planographic printing plate samples.

1. A positive working planographic printing plate material comprising an aluminum support and provided thereon, a light sensitive layer, wherein the light sensitive layer contains an alkali soluble resin and pigment having on the surface a development restrainer.

2. The positive working planographic printing plate material of claim 1, wherein the development restrainer is a polyalkylene glycol compound.

3. The positive working planographic printing plate material of claim 1, wherein the pigment is carbon black or a phthalocyanine pigment.

4. The positive working planographic printing plate material of claim 1, wherein in the pigment having on the surface a development restrainer, the pigment is chemically combined with the development restrainer.

5. The positive working planographic printing plate material of claim 1, wherein the light sensitive layer further contains an acid generating agent or an acid decomposable compound.

6. The positive working planographic printing plate material of claim 5, wherein the light sensitive layer further contains an acid generating agent and an acid decomposable compound.

7. A positive working planographic printing plate material comprising an aluminum support and provided thereon, a lower light sensitive layer and an upper light sensitive layer in that order, each layer containing an alkali soluble resin, wherein at least one of the lower and upper light sensitive layers contains a pigment having on the surface a development restrainer.

8. The positive working planographic printing plate material of claim 7, wherein the development restrainer is a polyalkylene glycol compound.

9. The positive working planographic printing plate material of claim 7, wherein the pigment is carbon black or a phthalocyanine pigment.

10. The positive working planographic printing plate material claim 7, wherein in the pigment having on the surface a development restrainer, the pigment is chemically combined with the development restrainer.

11. The positive working planographic printing plate material of claim 7, wherein the lower light sensitive layer contains the pigment having on the surface a development restrainer.

12. The positive working planographic printing plate material of claim 11, wherein the upper light sensitive layer contains an infrared absorbing dye.

13. The positive working planographic printing plate material of claim 11, wherein the lower layer further contains an acid generating agent or an acid decomposable compound.

14. The positive working planographic printing plate material of claim 13, wherein the lower layer further contains an acid generating agent and an acid decomposable compound.

15. A manufacturing process of a planographic printing plate comprising the steps of:
imagewise exposing the positive working light sensitive planographic printing plate material of claim 1, employing a laser having an emission wavelength of from 700 to 900 nm; and
developing the exposed positive working light sensitive planographic printing plate material with a developer with a pH of less than 13.0.

16. A manufacturing process of a planographic printing plate comprising the steps of:
imagewise exposing the positive working light sensitive planographic printing plate material of claim 7, employing a laser having an emission wavelength of from 700 to 900 nm; and
developing the exposed positive working light sensitive planographic printing plate material with a developer with a pH of less than 13.0.

17. A manufacturing process of a planographic printing plate comprising the steps of:
imagewise exposing the positive working light sensitive planographic printing plate material of claim 14, employing a laser having an emission wavelength of from 700 to 900 nm; and
developing the exposed positive working light sensitive planographic printing plate material with a developer with a pH of less than 13.0.
